(19) United States
(12) Patent Application Publication
(10) Pub. No.: US 2025/0120168 A1
(43) Pub. Date: Apr. 10, 2025

(54) SEMICONDUCTOR DEVICE

(71) Applicant: Mitsubishi Electric Corporation, Tokyo (JP)

(72) Inventors: Tetsuya HIGASHI, Tokyo (JP); Kazuya KONISHI, Tokyo (JP); Kakeru OTSUKA, Tokyo (JP)

(73) Assignee: Mitsubishi Electric Corporation, Tokyo (JP)

(21) Appl. No.: 18/810,030

(22) Filed: Aug. 20, 2024

(30) Foreign Application Priority Data
Oct. 5, 2023 (JP) 2023-173468

(51) Int. Cl. H01L 27/06; H01L 29/06; H01L 29/08; H01L 29/417; H01L 29/66; H01L 29/739; H01L 29/861

(52) U.S. Cl. CPC H10D 84/617; H10D 8/045; H10D 8/422; H10D 12/038; H10D 12/481; H10D 62/107; H10D 62/127; H10D 62/133; H10D 64/231

(57) ABSTRACT

A semiconductor device includes a semiconductor substrate on which a plurality of trenches are formed, an interlayer insulating film formed on the semiconductor substrate, a contact hole made in the interlayer insulating film, and an electrode connected to a semiconductor mesa portion that is a portion between the trenches of the semiconductor substrate through the contact hole. A side wall of the contact hole has a stepped shape having at least one step. A bottom of the contact hole is located on the semiconductor mesa portion, and an upper end of the contact hole is located outside the semiconductor mesa portion.

### BACKGROUND OF THE INVENTION

### Field of the Invention

The present disclosure relates to a semiconductor device.

### DESCRIPTION OF THE BACKGROUND ART

For example, Japanese Patent Application Laid-Open No. 2007-207784 discloses a technique for forming a contact hole by self-alignment as a method for shrinking dimensions of a semiconductor device.

As the semiconductor device is miniaturized, a size of the contact hole is reduced, and there is a concern that a void is formed in a contact plug (hereinafter, simply referred to as a “contact”) in the contact hole. In Japanese Patent Application Laid-Open No. 2007-207784, formation of a contact hole in a semiconductor device that is miniaturized is not considered, and formation of the void in the contact cannot be sufficiently prevented.

### SUMMARY

An object of the present disclosure is to provide a technique capable of preventing the formation of the void in the contact of the semiconductor device.

A semiconductor device according to the present disclosure includes: a semiconductor substrate on which a plurality of trenches are formed; an interlayer insulating film formed on the semiconductor substrate; a contact hole made in the interlayer insulating film; and an electrode that is formed on the interlayer insulating film and connected to a semiconductor mesa portion that is a portion between the trenches of the semiconductor substrate through the contact hole. A side wall of the contact hole has a stepped shape having at least one step. A bottom of the contact hole is located on the semiconductor mesa portion, and an upper end of the contact hole is located outside the semiconductor mesa portion.

According to the present disclosure, the formation of the void in the contact of the semiconductor device can be prevented.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view illustrating a chip of a semiconductor device according to a first preferred embodiment;

FIG. 2 is a plan view illustrating a chip of the semiconductor device according to the first preferred embodiment;

FIG. 3 is a plan view illustrating an IGBT region of the semiconductor device according to the first preferred embodiment;

FIG. 4 is a sectional view illustrating the IGBT region of the semiconductor device according to the first preferred embodiment;

FIG. 5 is a sectional view illustrating the IGBT region of the semiconductor device according to the first preferred embodiment;

FIG. 6 is a plan view illustrating a diode region of the semiconductor device according to the first preferred embodiment;

FIG. 7 is a sectional view illustrating the diode region of the semiconductor device according to the first preferred embodiment;

FIG. 8 is a sectional view illustrating the diode region of the semiconductor device according to the first preferred embodiment;

FIG. 9 is a sectional view illustrating a boundary between the IGBT region and the diode region of the semiconductor device according to the first preferred embodiment;

FIG. 10 is a sectional view illustrating a termination region of the semiconductor device according to the first preferred embodiment;

FIG. 11 is a sectional view illustrating the termination region of the semiconductor device according to the first preferred embodiment;

FIG. 12 is a view illustrating a method for manufacturing the semiconductor device according to the first preferred embodiment;

FIG. 13 is a view illustrating the method for manufacturing the semiconductor device according to the first preferred embodiment;

FIG. 14 is a view illustrating the method for manufacturing the semiconductor device according to the first preferred embodiment;

FIG. 15 is a view illustrating the method for manufacturing the semiconductor device according to the first preferred embodiment;

FIG. 16 is a view illustrating the method for manufacturing the semiconductor device according to the first preferred embodiment;

FIG. 17 is a view illustrating the method for manufacturing the semiconductor device according to the first preferred embodiment;

FIG. 18 is a view illustrating the method for manufacturing the semiconductor device according to the first preferred embodiment;

FIG. 19 is a view illustrating the method for manufacturing the semiconductor device according to the first preferred embodiment;

FIG. 20 is a view illustrating the method for manufacturing the semiconductor device according to the first preferred embodiment;

FIG. 21 is a view illustrating the method for manufacturing the semiconductor device according to the first preferred embodiment;

FIG. 22 is a view illustrating the method for manufacturing the semiconductor device according to the first preferred embodiment;

FIG. 23 is a view illustrating the method for manufacturing the semiconductor device according to the first preferred embodiment;

FIG. 24 is a view illustrating a configuration of a contact of the semiconductor device according to the first preferred embodiment;

FIG. 25 is a process drawing illustrating a process of forming a contact hole;

FIG. 26 is a process drawing illustrating the process of forming the contact hole;

FIG. 27 is a process drawing illustrating the process of forming the contact hole;

FIG. 28 is a process drawing illustrating the process of forming the contact hole;

FIG. 29 is a view illustrating an example of a shape of a frame-shaped insulating film remaining on a step of the contact hole;

FIG. 30 is a view illustrating an example of the shape of the frame-shaped insulating film remaining on the step of the contact hole;

FIG. 31 is a view illustrating an example of the shape of the frame-shaped insulating film remaining on the step of the contact hole;

FIG. 32 is a view illustrating a modification of the contact of the semiconductor device according to the first preferred embodiment;

FIG. 33 is a view illustrating a configuration of a contact of a semiconductor device according to a second preferred embodiment;

FIG. 34 is a view illustrating a modification of the contact of the semiconductor device according to the second preferred embodiment;

FIG. 35 is a view illustrating a modification of the contact of the semiconductor device according to the second preferred embodiment;

FIG. 36 is a view illustrating a modification of the contact of the semiconductor device according to the second preferred embodiment; and

FIG. 37 is a view illustrating a disposition example of contacts of the semiconductor device.

### DESCRIPTION OF THE PREFERRED EMBODIMENTS

In the following description, an n-type and a p-type represent a conductivity type of a semiconductor, and in the present disclosure, a first conductivity type is described as the n-type and a second conductivity type is described as the p-type. However, the first conductivity type may be the p-type and the second conductivity type may be the n-type. In addition, n⁻ indicates that impurity concentration is lower than n, and n⁺ indicates that the impurity concentration is higher than n. Similarly, p⁻ indicates that the impurity concentration is lower than p, and p⁺ indicates that the impurity concentration is higher than p.

In addition, a height of the impurity concentration of each region is defined by a peak concentration. That is, the region having a high (or low) impurity concentration means a region having a high (or low) impurity peak concentration.

### First Preferred Embodiment

Hereinafter, a configuration of a semiconductor device according to a first preferred embodiment will be described. A metal oxide semiconductor field effect transistor (MOSFET), an insulated gate bipolar transistor (IGBT), a reverse conducting IGBT (RC-IGBT), a Schottky barrier diode (SBD), a PN diode, and the like are assumed as a semiconductor element included in the semiconductor device, but in this case, the semiconductor element is assumed to be an RC-IGBT.

A material of the semiconductor element may be silicon (Si) or a wide band gap semiconductor such as silicon carbide (SiC). The semiconductor device formed using the wide band gap semiconductor is excellent in operation at high voltage, large current, and high temperature as compared with the semiconductor device using silicon. Examples of the wide bandgap semiconductor include gallium nitride (GaN)-based materials and diamond in addition to silicon carbide.

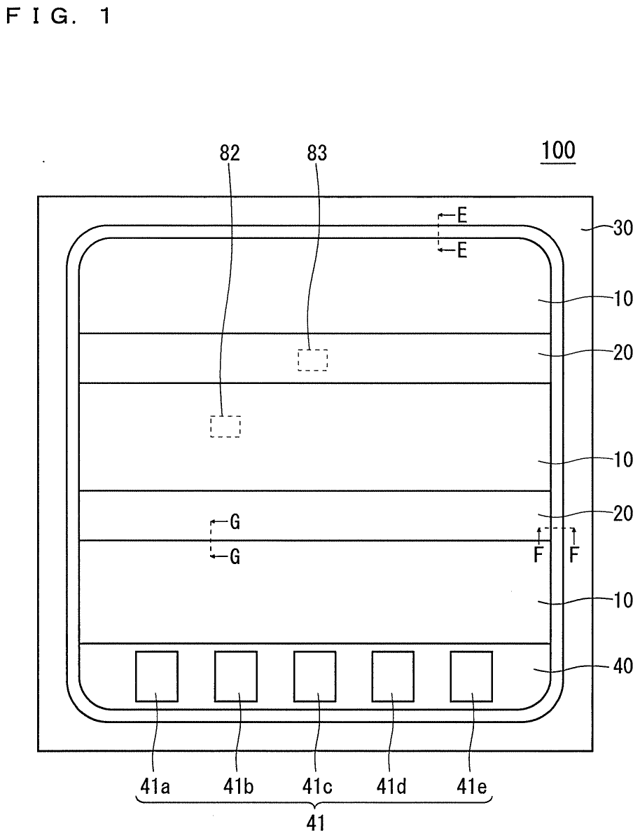

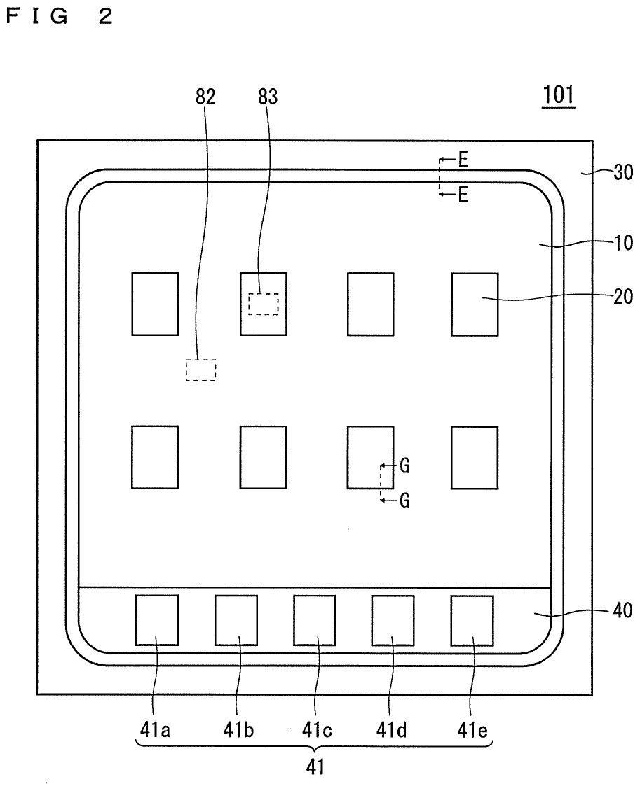

FIG. 1 is a plan view illustrating a semiconductor device that is an RC-IGBT. FIG. 2 is a plan view illustrating a semiconductor device that is an RC-IGBT having another configuration. A semiconductor device 100 in FIG. 1 is provided while an IGBT region 10 and a diode region 20 are disposed in a stripe shape, and may be simply referred to as a “stripe type”. In a semiconductor device 101 in FIG. 2, a plurality of diode regions 20 in a longitudinal direction and a lateral direction and the IGBT region 10 is provided around the diode region 20. The semiconductor device 101 may be simply referred to as an “island type”.

### (1) Overall Planar Structure of Stripe Type

In FIG. 1, the semiconductor device 100 includes the IGBT region 10 and the diode region 20 in one semiconductor device. The IGBT region 10 and the diode region 20 extend from one end side to the other end side of the semiconductor device 100, and are alternately provided in the stripe shape in a direction orthogonal to an extending direction of the IGBT region 10 and the diode region 20. In FIG. 1, three IGBT regions 10 and two diode regions 20 are illustrated, and all the diode regions 20 are sandwiched between the IGBT regions 10. However, numbers of the IGBT regions 10 and the diode regions 20 are not limited thereto, and the number of the IGBT regions 10 may be equal to and greater than three and equal to or smaller than three, and the number of the diode regions 20 may be equal to or greater than two and equal to or smaller than two. In addition, locations of the IGBT region 10 and the diode region 20 in FIG. 1 may be interchanged, or all the IGBT regions 10 may be sandwiched between the diode regions 20. In addition, the IGBT region 10 and the diode region 20 may be provided adjacent to each other one by one.

As illustrated in FIG. 1, a pad region 40 is provided adjacent to a lower side of a drawing of the IGBT region 10. The pad region 40 is a region where a control pad 41 controlling the semiconductor device 100 is provided. The IGBT region 10 and the diode region 20 are collectively referred to as a cell region. A termination region 30 is provided around a combined region of the cell region and the pad region 40 in order to maintain a withstand voltage of the semiconductor device 100. A known withstand voltage holding structure can be appropriately selected and provided in the termination region 30. For example, the withstand voltage holding structure may be configured by providing a field limiting ring (FLR) surrounding a combined region of the cell region and the pad region 40 with a p-type termination well layer of a p-type semiconductor or a variation of lateral doping (VLD) surrounding a combined region of the cell region and the pad region 40 with a p-type termination well layer in which a concentration gradient is provided on a first main surface side that is a front surface side of the semiconductor device 100, and the number of ring-shaped p-type termination well layers used for the FLR and a concentration distribution used for the VLD may be appropriately selected according to the withstand voltage design of the semiconductor device 100. In addition, the p-type termination well layer may be provided over substantially the entire pad region 40, and an IGBT cell and a diode cell may be provided in the pad region 40.

For example, the control pad 41 may be a current sense pad 41a, a Kelvin emitter pad 41b, a gate pad 41c, and temperature sense diode pads 41d, 41e. The current sense pad 41a is the control pad detecting the current flowing through the cell region of the semiconductor device 100, and is the control pad electrically connected to IGBT cells or diode cells in a part of the cell region such that, when the current flows through the cell region of the semiconductor device 100, a several part to a several tens of thousands of part of the current flowing through the entire cell region flows.

The Kelvin emitter pad 41b and the gate pad 41c are control pads to which a gate drive voltage controlling on and off of the semiconductor device 100 is applied. The Kelvin emitter pad 41b is electrically connected to the p-type base layer and an n⁺-type emitter layer of the IGBT cell, and the gate pad 41c is electrically connected to the gate trench electrode of the IGBT cell. The Kelvin emitter pad 41b and the p-type base layer may be electrically connected through an p⁺-type contact layer. The temperature sense diode pads 41d, 41e are control pads electrically connected to an anode and a cathode of a temperature sense diode provided in the semiconductor device 100. The voltage between the anode and the cathode of the temperature sense diode (not illustrated) provided in the cell region is measured to measure temperature at the semiconductor device 100.

### (2) Overall Planar Structure of Island Type

In FIG. 2, the semiconductor device 101 includes the IGBT region 10 and the diode region 20 in one semiconductor device. A plurality of diode regions 20 are arranged side by side in the longitudinal direction and the lateral direction in the semiconductor device, and the diode region 20 is surrounded by the IGBT region 10. That is, the plurality of diode regions 20 are provided in the island shape in the IGBT region 10. In FIG. 2, the diode regions 20 are provided in a matrix of four columns in a horizontal direction on the drawing and two rows in an upper limit direction on the drawing. However, the number and arrangement of the diode regions 20 are not limited to this, and one or a plurality of diode regions 20 may be provided in the IGBT region 10 in an interspersed manner, and each diode region 20 may be surrounded by the IGBT region 10.

As illustrated in FIG. 2, the pad region 40 is provided adjacent to the lower side of the drawing of the IGBT region 10. The pad region 40 is a region where the control pad 41 controlling the semiconductor device 101 is provided. The IGBT region 10 and the diode region 20 are collectively referred to as a cell region. The termination region 30 is provided around a combined region of the cell region and the pad region 40 in order to maintain a withstand voltage of the semiconductor device 101. A known withstand voltage holding structure can be appropriately selected and provided in the termination region 30. For example, the withstand voltage holding structure may be configured by providing the field limiting ring (FLR) surrounding the combined region of the cell region and the pad region 40 with the p-type termination well layer of the p-type semiconductor or the variation of lateral doping (VLD) surrounding the combined region of the cell region and the pad region 40 with the p-type termination well layer in which the concentration gradient is provided on the first main surface side that is the front surface side of the semiconductor device 101, and the number of ring-shaped p-type termination well layers used for the FLR and the concentration distribution used for the VLD may be appropriately selected according to the withstand voltage design of the semiconductor device 101. In addition, the p-type termination well layer may be provided over substantially the entire pad region 40, and an IGBT cell and a diode cell may be provided in the pad region 40.

For example, the control pad 41 may be a current sense pad 41a, a Kelvin emitter pad 41b, a gate pad 41c, and temperature sense diode pads 41d, 41e. The current sense pad 41a is a control pad detecting the current flowing through the cell region of the semiconductor device 101, and is a control pad electrically connected to IGBT cells or diode cells in a part of the cell region such that, when a current flows through the cell region of the semiconductor device 101, a several part to a several tens of thousands of part of the current flowing through the entire cell region flows.

The Kelvin emitter pad 41b and the gate pad 41c are control pads to which the gate drive voltage controlling on and off of the semiconductor device 101 is applied. The Kelvin emitter pad 41b is electrically connected to the p-type base layer and an n⁺-type emitter layer of the IGBT cell, and the gate pad 41c is electrically connected to the gate trench electrode of the IGBT cell. The Kelvin emitter pad 41b and the p-type base layer may be electrically connected through an p⁺-type contact layer. The temperature sense diode pads 41d, 41e are control pads electrically connected to the anode and the cathode of the temperature sense diode provided in the semiconductor device 101. The voltage between the anode and the cathode of the temperature sense diode (not illustrated) provided in the cell region is measured to measure the temperature at the semiconductor device 101.

### (3) Example of Structure of IGBT Region 10

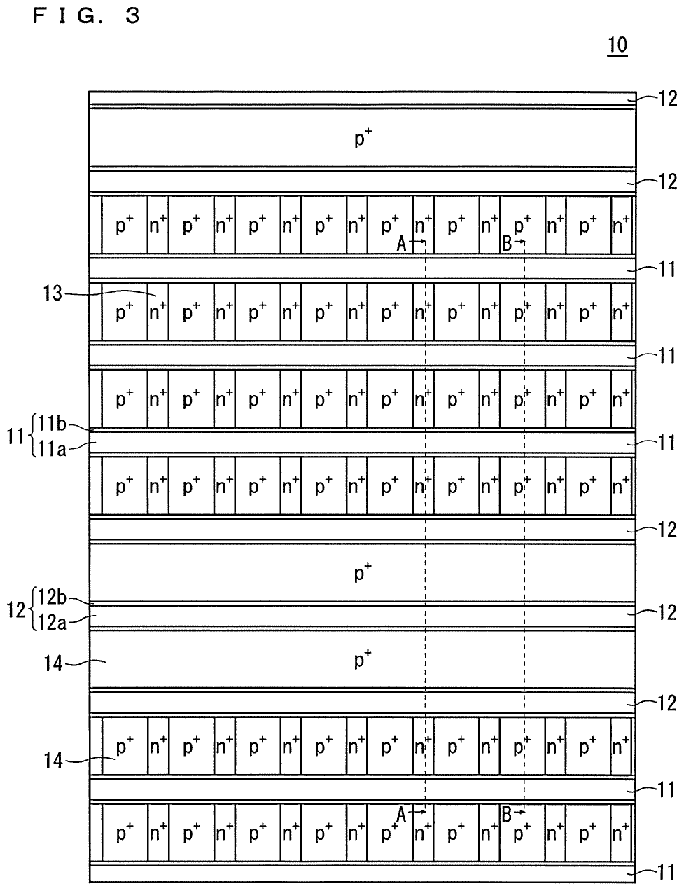

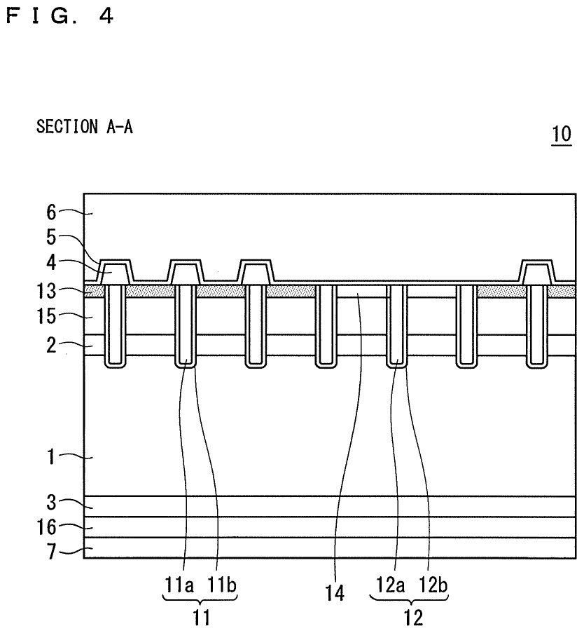

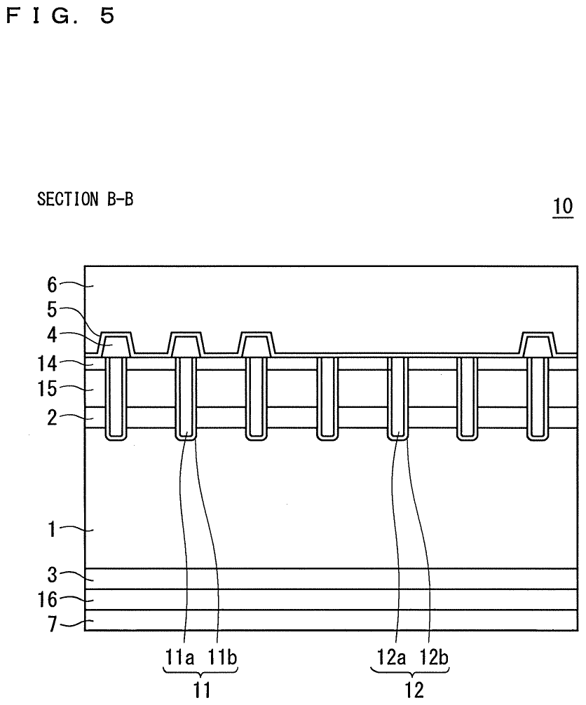

FIG. 3 is a partially enlarged plan view illustrating a configuration of the IGBT region of the semiconductor device that is the RC-IGBT. FIGS. 4 and 5 are sectional views illustrating a configuration of the IGBT region of the semiconductor device that is the RC-IGBT. FIG. 3 is an enlarged view illustrating a region surrounded by a broken line 82 in the semiconductor device 100 in FIG. 1 or the semiconductor device 101 in FIG. 2. FIG. 4 is a sectional view illustrating the semiconductor device 100 or the semiconductor device 101 in FIG. 3 taken along a broken line A-A, and FIG. 5 is a sectional view illustrating the semiconductor device 100 or the semiconductor device 101 in FIG. 3 taken along a broken line B-B.

As illustrated in FIG. 3, in the IGBT region 10, an active trench gate 11 and a dummy trench gate 12 are provided in a stripe shape. In the semiconductor device 100, the active trench gate 11 and the dummy trench gate 12 extend in a longitudinal direction of the IGBT region 10, and the longitudinal direction of the IGBT region 10 is the longitudinal direction of the active trench gate 11 and the dummy trench gate 12. On the other hand, in the semiconductor device 101, there is no particular distinction between the longitudinal direction and a lateral direction in the IGBT region 10, but the lateral direction in the drawing may be the longitudinal direction of the active trench gate 11 and the dummy trench gate 12, and a vertical direction in the drawing may be the longitudinal direction of the active trench gate 11 and the dummy trench gate 12.

The active trench gate 11 is configured such that a gate trench electrode 11a is provided in a trench formed in the semiconductor substrate through a gate trench insulating film 11b. The dummy trench gate 12 is configured such that a dummy trench electrode 12a is provided in the trench formed in the semiconductor substrate through a dummy trench insulating film 12b. The gate trench electrode 11a of the active trench gate 11 is electrically connected to the gate pad 41c. The dummy trench electrode 12a of the dummy trench gate 12 is electrically connected to the emitter electrode provided on the first main surface of the semiconductor device 100 or the semiconductor device 101.

An n⁺-type emitter layer 13 is provided on both sides in a width direction of the active trench gate 11 so as to be in contact with the gate trench insulating film 11b. The n⁺-type emitter layer 13 is a semiconductor layer containing, for example, arsenic or phosphorus as an n-type impurity, and the concentration of the n-type impurity is 1.0E+17/cm³ to 1.0E+20/cm³. The n⁺-type emitter layer 13 and a p⁺-type contact layer 14 are alternately provided along the extending direction of the active trench gate 11. The p⁺-type contact layer 14 is also provided between two adjacent dummy trench gates 12. The p⁺-type contact layer 14 is a semiconductor layer containing, for example, boron or aluminum as a p-type impurity, and the concentration of the p-type impurity is 1.0E+15/cm³ to 1.0E+20/cm³.

As illustrated in FIG. 3, in the IGBT region 10 of the semiconductor device 100 or the semiconductor device 101, three dummy trench gates 12 are arranged next to three active trench gates 11, and three active trench gates 11 are arranged next to three dummy trench gates 12. The IGBT region 10 has a configuration in which a set of active trench gates 11 and a set of dummy trench gates 12 are alternately arranged as described above. In FIG. 3, a number of active trench gates 11 included in one set of active trench gates 11 is three, but may be equal to or greater than one. In addition, the number of dummy trench gates 12 included in one set of one dummy trench gate 12 may be equal to or greater than one, and the number of dummy trench gates 12 may be zero. That is, all the trenches provided in the IGBT region 10 may be used as the active trench gate 11.

FIG. 4 is a sectional view illustrating the semiconductor device 100 or the semiconductor device 101 taken along a broken line A-A in FIG. 3, and is a sectional view of the IGBT region 10. The semiconductor device 100 or the semiconductor device 101 includes an n⁻-type drift layer 1 made of a semiconductor substrate. The n⁻-type drift layer 1 is a semiconductor layer containing, for example, arsenic or phosphorus as the n-type impurity, and the concentration of the n-type impurity is 1.0E+12/cm³ to 1.0E+15/cm³. In FIG. 4, the semiconductor substrate is in a range from the n⁺-type source layer 13 and the p⁺-type contact layer 14 to a p-type collector layer 16. In FIG. 4, the upper end of the drawing of the n⁺-type source layer 13 and the p⁺-type contact layer 14 is referred to as a first main surface of the semiconductor substrate, and the lower end of the drawing of the p-type collector layer 16 is referred to as a second main surface of the semiconductor substrate. The first main surface of the semiconductor substrate is a main surface on a front surface side of the semiconductor device 100, and the second main surface of the semiconductor substrate is a main surface on a back surface side of the semiconductor device 100. The semiconductor device 100 includes the n⁻-type drift layer 1 between the first main surface and the second main surface opposite to the first main surface in the IGBT region 10 that is the cell region.

As illustrated in FIG. 4, in the IGBT region 10, an n-type carrier accumulation layer 2 having a higher n-type impurity concentration than the n⁻-type drift layer 1 is provided on the first main surface side of the n⁻-type drift layer 1. The n-type carrier accumulation layer 2 is a semiconductor layer containing, for example, arsenic or phosphorus as the n-type impurity, and the concentration of the n-type impurity is 1.0E+13/cm³ to 1.0E+17/cm³. The semiconductor device 100 or the semiconductor device 101 may have a configuration in which the n⁻-type drift layer 1 is also provided in the region of the n-type carrier accumulation layer 2 in FIG. 4 without providing the n-type carrier accumulation layer 2. The provision of the n-type carrier accumulation layer 2 can reduce an energization loss when the current flows in the IGBT region 10. The n-type carrier accumulation layer 2 and the n⁻-type drift layer 1 may be collectively referred to as a drift layer.

The n-type carrier accumulation layer 2 is formed by ion-implanting the n-type impurity into the semiconductor substrate configuring the n⁻-type drift layer 1 and then diffusing the n-type impurity implanted by annealing into the semiconductor substrate that is the n⁻-type drift layer 1.

A p-type base layer 15 is provided on the first main surface side of the n-type carrier accumulation layer 2. The p-type base layer 15 is a semiconductor layer containing, for example, boron or aluminum as the p-type impurity, and the concentration of the p-type impurity is 1.0E+12/cm³ to 1.0E+19/cm³. The p-type base layer 15 is in contact with the gate trench insulating film 11b of the active trench gate 11. On the first main surface side of the p-type base layer 15, the n⁺-type emitter layer 13 is provided in contact with the gate trench insulating film 11b of the active trench gate 11, and the p⁺-type contact layer 14 is provided in the remaining region. The n⁺-type emitter layer 13 and the p⁺-type contact layer 14 configure the first main surface of the semiconductor substrate. The p⁺-type contact layer 14 is a region having a higher p-type impurity concentration than the p-type base layer 15, and when the p⁺-type contact layer 14 and the p-type base layer 15 are required to be distinguished from each other, they may be referred to individually, and the p⁺-type contact layer 14 and the p-type base layer 15 may be collectively referred to as a p-type base layer.

In the semiconductor device 100 or the semiconductor device 101, an n-type buffer layer 3 having a higher concentration of the n-type impurity than the n⁻-type drift layer 1 is provided on the second main surface side of the n⁻-type drift layer 1. The n-type buffer layer 3 is provided to prevent punch-through of a depletion layer extending from the p-type base layer 15 to the second main surface side when the semiconductor device 100 is in an off-state. The n-type buffer layer 3 may be formed by, for example, implanting the phosphorus (P) or proton (H⁺), or implanting both the phosphorus (P) and the proton (H⁺). The concentration of the n-type impurity in the n-type buffer layer 3 is 1.0E+12/cm³ to 1.0E+18/cm³.

The semiconductor device 100 or the semiconductor device 101 may have a configuration in which the n⁻-type drift layer 1 is also provided in the region of the n-type buffer layer 3 in FIG. 4 without providing the n-type buffer layer 3. The n-type buffer layer 3 and the n⁻-type drift layer 1 may be collectively referred to as a drift layer.

In the semiconductor device 100 or the semiconductor device 101, the p-type collector layer 16 is provided on the second main surface side of the n-type buffer layer 3. That is, the p-type collector layer 16 is provided between the n⁻-type drift layer 1 and the second main surface. The p-type collector layer 16 is a semiconductor layer containing, for example, boron or aluminum as the p-type impurity, and the concentration of the p-type impurity is 1.0E+16/cm³ to 1.0E+20/cm³. The p-type collector layer 16 configures the second main surface of the semiconductor substrate. The p-type collector layer 16 is provided not only in the IGBT region 10 but also in the termination region 30, and a portion of the p-type collector layer 16 provided in the termination region 30 configures a p-type termination collector layer 16a. In addition, the p-type collector layer 16 may be provided so as to partially protrude from the IGBT region 10 to the diode region 20.

As illustrated in FIG. 4, the trench that penetrates the p-type base layer 15 from the first main surface of the semiconductor substrate and reaches the n⁻-type drift layer 1 is formed in the semiconductor device 100 or the semiconductor device 101. The gate trench electrode 11a is provided in the trench through the gate trench insulating film 11b to configure the active trench gate 11. The gate trench electrode 11a is opposite to the n⁻-type drift layer 1 through the gate trench insulating film 11b. The dummy trench electrode 12a is provided in the trench through the dummy trench insulating film 12b to configure the dummy trench gate 12. The dummy trench electrode 12a is opposite to the n⁻-type drift layer 1 through the dummy trench insulating film 12b. The gate trench insulating film 11b of the active trench gate 11 is in contact with the p-type base layer 15 and the n⁺-type emitter layer 13. When the gate drive voltage is applied to the gate trench electrode 11a, a channel is formed in the p-type base layer 15 that is in contact with the gate trench insulating film 11b of the active trench gate 11.

As illustrated in FIG. 4, an interlayer insulating film 4 is provided on the gate trench electrode 11a of the active trench gate 11. A barrier metal 5 is formed on the region of the first main surface of the semiconductor substrate where the interlayer insulating film 4 is not provided and on the interlayer insulating film 4. For example, the barrier metal 5 may be a conductor containing titanium (Ti), and may be titanium nitride or TiSi obtained by alloying titanium and silicon (Si). As illustrated in FIG. 4, the barrier metal 5 is in ohmic contact with the n⁺-type emitter layer 13, the p⁺-type contact layer 14, and the dummy trench electrode 12a, and is electrically connected to the n⁺-type emitter layer 13, the p⁺-type contact layer 14, and the dummy trench electrode 12a. An emitter electrode 6 is provided on the barrier metal 5. For example, the emitter electrode 6 may be formed of an aluminum alloy such as an aluminum silicon alloy (Al—Si-based alloy), or may be an electrode including a plurality of layers of metal films in which a plating film is formed on an electrode formed of an aluminum alloy by electroless plating or electrolytic plating. For example, the plating film formed by the electroless plating or the electrolytic plating may be a nickel (Ni) plating film. In addition, in the case of a fine region between adjacent interlayer insulating films 4 or the like and a region where favorable embedding cannot be obtained in the emitter electrode 6, tungsten having better embeddability than the emitter electrode 6 may be disposed in the fine region, and the emitter electrode 6 may be provided on the tungsten. The emitter electrode 6 may be provided on the n⁺-type emitter layer 13, the p⁺-type contact layer 14, and the dummy trench electrode 12a without providing the barrier metal 5. Alternatively, the barrier metal 5 may be provided only on the n-type semiconductor layer such as the n⁺-type emitter layer 13. The barrier metal 5 and the emitter electrode 6 may be collectively referred to as an emitter electrode. Although FIG. 4 illustrates a view in which the interlayer insulating film 4 is not provided on the dummy trench electrode 12a of the dummy trench gate 12, the interlayer insulating film 4 may be formed on the dummy trench electrode 12a of the dummy trench gate 12. When the interlayer insulating film 4 is formed on the dummy trench electrode 12a of the dummy trench gate 12, the emitter electrode 6 and the dummy trench electrode 12a may be electrically connected in another section.

The interlayer insulating film 4 will be described in detail in “(8) sectional shape of contact” described later.

A collector electrode 7 is provided on the second main surface side of the p-type collector layer 16. Similarly to the emitter electrode 6, the collector electrode 7 may be made of an aluminum alloy or an aluminum alloy and a plating film. The collector electrode 7 may have a configuration different from that of the emitter electrode 6. The collector electrode 7 is in ohmic contact with the p-type collector layer 16 and is electrically connected to the p-type collector layer 16.

FIG. 5 is a sectional view illustrating the semiconductor device 100 or the semiconductor device 101 taken along a broken line B-B in FIG. 3, and is a sectional view illustrating the IGBT region 10. The sectional view taken along the broken line A-A illustrated in FIG. 4 is different from the sectional view taken along the broken line B-B in FIG. 5 in that the n⁺-type emitter layer 13 provided on the first main surface side of the semiconductor substrate in contact with the active trench gate 11 is not seen. That is, as illustrated in FIG. 3, the n⁺-type emitter layer 13 is selectively provided on the first main surface side of the p-type base layer. The p-type base layer referred to herein is a p-type base layer in which the p-type base layer 15 and the p⁺-type contact layer 14 are collectively referred to.

### (4) Example of Structure of Diode Region 20

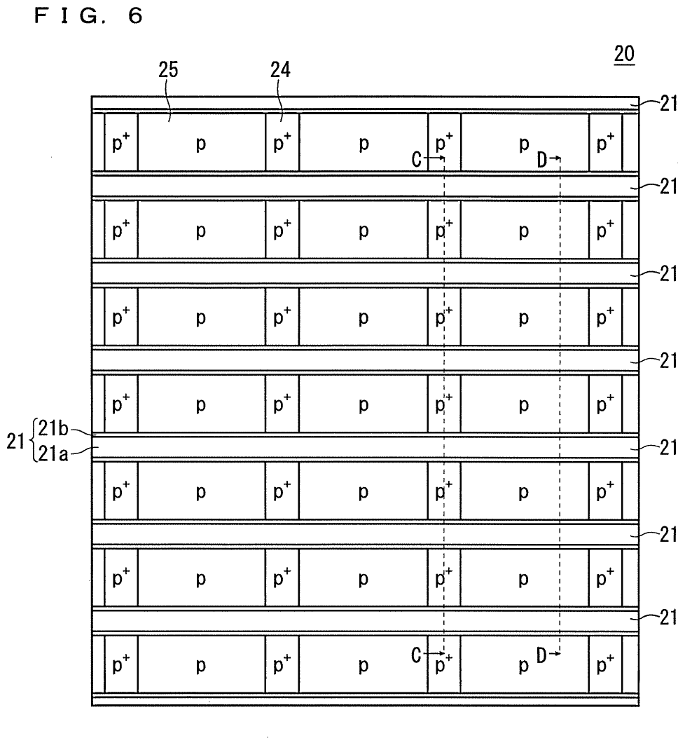

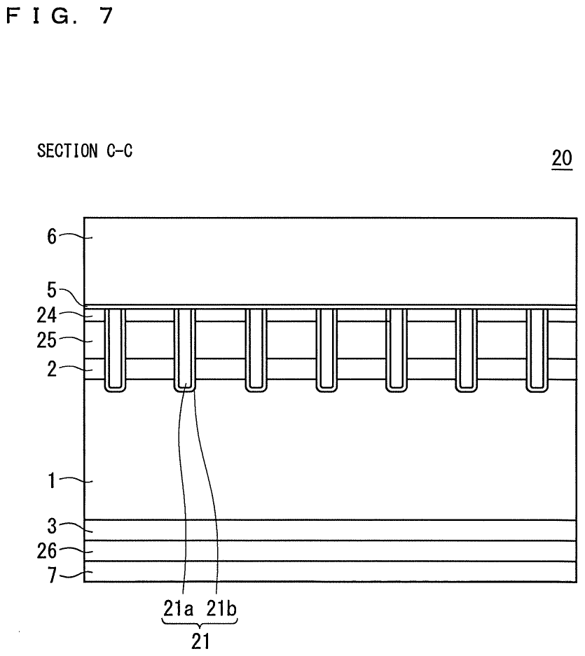

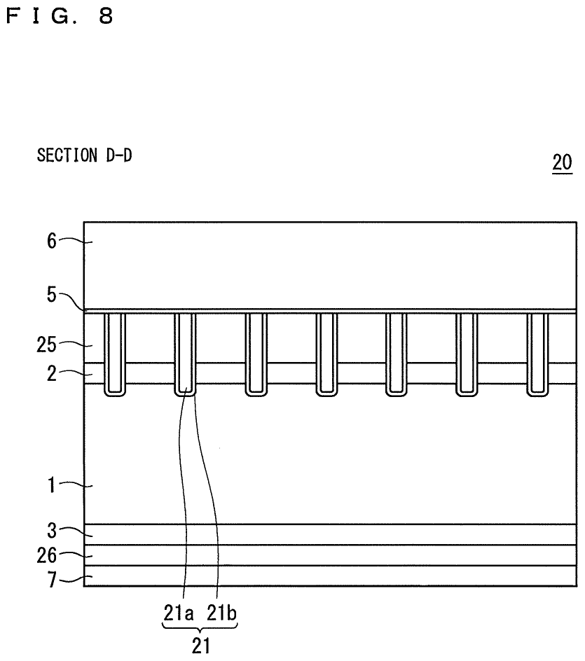

FIG. 6 is a partially enlarged plan view illustrating a configuration of the diode region of the semiconductor device that is the RC-IGBT. FIGS. 7 and 8 are sectional views illustrating the configuration of the diode region of the semiconductor device that is the RC-IGBT. FIG. 6 is an enlarged view of a region surrounded by a broken line 83 in the semiconductor device 100 or the semiconductor device 101 in FIG. 1. FIG. 7 is a sectional view taken along a broken line C-C of the semiconductor device 100 in FIG. 6. FIG. 8 is a sectional view taken along a broken line D-D of the semiconductor device 100 in FIG. 6.

A diode trench gate 21 extends along the first main surface of the semiconductor device 100 or the semiconductor device 101 from one end side of the diode region 20, which is the cell region, toward the opposite end side. The diode trench gate 21 is configured by providing a diode trench electrode 21a in the trench formed in the semiconductor substrate of the diode region 20 through a diode trench insulating film 21b. The diode trench electrode 21a is opposite to the n⁻-type drift layer 1 through the diode trench insulating film 21b. A p⁺-type contact layer 24 and a p-type anode layer 25 are provided between the two adjacent diode trench gates 21. The p⁺-type contact layer 24 is a semiconductor layer containing, for example, boron or aluminum as a p-type impurity, and the concentration of the p-type impurity is 1.0E+15/cm³ to 1.0E+20/cm³. The p-type anode layer 25 is a semiconductor layer containing, for example, boron or aluminum as the p-type impurity, and the concentration of the p-type impurity is 1.0E+12/cm³ to 1.0E+19/cm³. The p⁺-type contact layer 24 and the p-type anode layer 25 are alternately provided in the longitudinal direction of the diode trench gate 21.

FIG. 7 is a sectional view illustrating the semiconductor device 100 or the semiconductor device 101 taken along the broken line C-C in FIG. 6, and is a sectional view illustrating the diode region 20. The semiconductor device 100 or the semiconductor device 101 also includes the n⁻-type drift layer 1 made of the semiconductor substrate in the diode region 20 similarly to the IGBT region 10. The n⁻-type drift layer 1 of the diode region 20 and the n⁻-type drift layer 1 of the IGBT region 10 are continuously and integrally formed, and are formed of the same semiconductor substrate. In FIG. 7, the semiconductor substrate ranges from the p⁺-type contact layer 24 to an n⁺-type cathode layer 26. In FIG. 7, the upper end of the drawing of the p⁺-type contact layer 24 is referred to as the first main surface of the semiconductor substrate, and the lower end of the drawing of the n⁺-type cathode layer 26 is referred to as the second main surface of the semiconductor substrate. The first main surface of the diode region 20 and the first main surface of the IGBT region 10 are flush, and the second main surface of the diode region 20 and the second main surface of the IGBT region 10 are flush.

As illustrated in FIG. 7, also in the diode region 20, similarly to the IGBT region 10, the n-type carrier accumulation layer 2 is provided on the first main surface side of the n⁻-type drift layer 1, and the n-type buffer layer 3 is provided on the second main surface side of the n⁻-type drift layer 1. The n-type carrier accumulation layer 2 and the n-type buffer layer 3 that are provided in the diode region 20 have the same configuration as the n-type carrier accumulation layer 2 and the n-type buffer layer 3 that are provided in the IGBT region 10. The n-type carrier accumulation layer 2 is not necessarily provided in the IGBT region 10 and the diode region 20, and the n-type carrier accumulation layer 2 may not be provided in the diode region 20 even when the n-type carrier accumulation layer 2 is provided in the IGBT region 10. Similarly to the IGBT region 10, the n⁻-type drift layer 1, the n-type carrier accumulation layer 2, and the n-type buffer layer 3 may be collectively referred to as a drift layer.

The p-type anode layer 25 is provided on the first main surface side of the n-type carrier accumulation layer 2. The p-type anode layer 25 is provided between the n⁻-type drift layer 1 and the first main surface. In the p-type anode layer 25, the p-type anode layer 25 and the p-type base layer 15 may be simultaneously formed by making the concentration of the p-type impurity the same as that of the p-type base layer 15 of the IGBT region 10. In addition, the concentration of the p-type impurity of the p-type anode layer 25 may be lower than the concentration of the p-type impurity of the p-type base layer 15 of the IGBT region 10 to reduce an amount of holes implanted into the diode region 20 during diode operation. A recovery loss during the diode operation can be reduced by reducing the amount of holes implanted during the diode operation.

The p⁺-type contact layer 24 is provided on the first main surface side of the p-type anode layer 25. The concentration of the p-type impurity of the p⁺-type contact layer 24 may be the same as or different from the concentration of the p-type impurity of the p⁺-type contact layer 14 of the IGBT region 10. The p⁺-type contact layer 24 configures the first main surface of the semiconductor substrate. When the p⁺-type contact layer 24 is a region having a higher concentration of the p-type impurity than the p-type anode layer 25, and when the p⁺-type contact layer 24 and the p-type anode layer 25 are required to be distinguished from each other, they may be referred to individually, and the p⁺-type contact layer 24 and the p-type anode layer 25 may be collectively referred to as a p-type anode layer.

In the diode region 20, the n⁺-type cathode layer 26 is provided on the second main surface side of the n-type buffer layer 3. The n⁺-type cathode layer 26 is provided between the n⁻-type drift layer 1 and the second main surface. The n⁺-type cathode layer 26 is a semiconductor layer containing, for example, arsenic or phosphorus as the n-type impurity, and the concentration of the n-type impurity is 1.0E+16/cm³ to 1.0E+21/cm³. As illustrated in FIG. 2, the n⁺-type cathode layer 26 is provided in a part or all of the diode region 20. The n⁺-type cathode layer 26 configures the second main surface of the semiconductor substrate. Although not illustrated, the p-type impurity may be further selectively implanted into the region where the n⁺-type cathode layer 26 is formed as described above, and the p-type cathode layer may be provided using a part of the region where the n⁺-type cathode layer 26 is formed as the p-type semiconductor.

As illustrated in FIG. 7, the trench that penetrates the p-type anode layer 25 from the first main surface of the semiconductor substrate and reaches the n⁻-type drift layer 1 is formed in the diode region 20 of the semiconductor device 100 or the semiconductor device 101. The diode trench electrode 21a is provided in the trench of the diode region 20 through the diode trench insulating film 21b to configure the diode trench gate 21. The diode trench electrode 21a is opposite to the n⁻-type drift layer 1 through the diode trench insulating film 21b.

As illustrated in FIG. 7, the barrier metal 5 is provided on the diode trench electrode 21a and the p⁺-type contact layer 24. The barrier metal 5 is in ohmic contact with the diode trench electrode 21a and the p⁺-type contact layer 24, and is electrically connected to the diode trench electrode and the p⁺-type contact layer 24. The barrier metal 5 may have the same configuration as the barrier metal 5 in the IGBT region 10. An emitter electrode 6 is provided on the barrier metal 5. The emitter electrode 6 provided in the diode region 20 is formed continuously with the emitter electrode 6 provided in the IGBT region 10. Similarly to the IGBT region 10, the diode trench electrode 21a and the p⁺-type contact layer 24 may be brought into ohmic contact with the emitter electrode 6 without providing the barrier metal 5. Although FIG. 7 illustrates a view in which the interlayer insulating film 4 is not provided on the diode trench electrode 21a of the diode trench gate 21, the interlayer insulating film 4 may be formed on the diode trench electrode 21a of the diode trench gate 21. When the interlayer insulating film 4 is formed on the diode trench electrode 21a of the diode trench gate 21, the emitter electrode 6 and the diode trench electrode 21a may be electrically connected to each other in another section.

The collector electrode 7 is provided on the second main surface side of the n⁺-type cathode layer 26. Similarly to the emitter electrode 6, the collector electrode 7 of the diode region 20 is formed continuously with the collector electrode 7 provided in the IGBT region 10. The collector electrode 7 is in ohmic contact with the n⁺-type cathode layer 26 and is electrically connected to the n⁺-type cathode layer 26.

FIG. 8 is a sectional view illustrating the semiconductor device 100 or the semiconductor device 101 taken along the broken line D-D in FIG. 6, and is a sectional view illustrating the diode region 20. The sectional view in FIG. 8 is different from the sectional view indicated by the broken line C-C in FIG. 7 in that the p⁺-type contact layer 24 is not provided between the p-type anode layer 25 and the barrier metal 5 and the p-type anode layer 25 configures the first main surface of the semiconductor substrate. That is, the p⁺-type contact layer 24 in FIG. 7 is selectively provided on the first main surface side of the p-type anode layer 25.

### (5) Boundary Region Between IGBT Region 10 and Diode Region 20

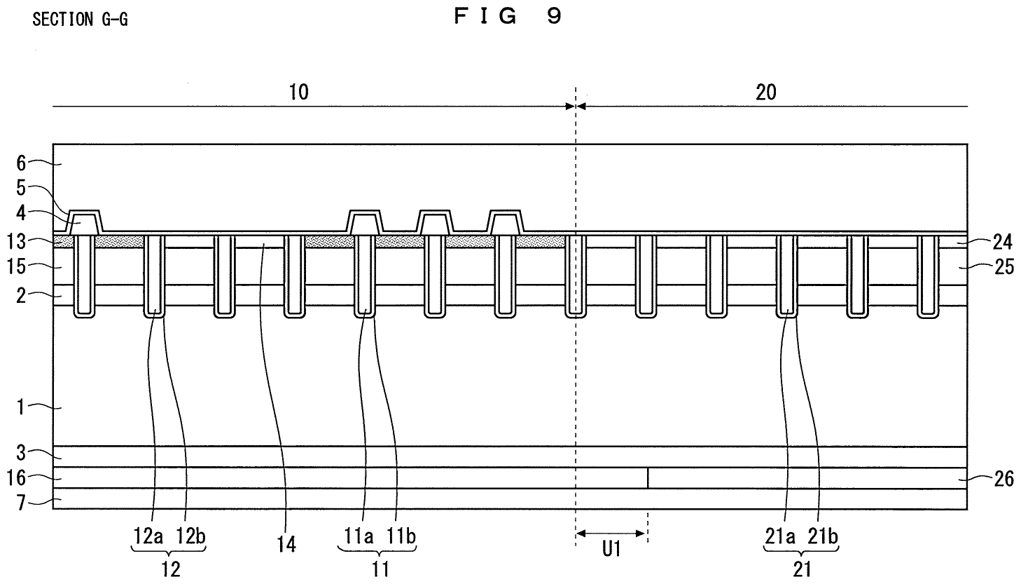

FIG. 9 is a sectional view illustrating a configuration of a boundary between the IGBT region and the diode region of the semiconductor device that is the RC-IGBT. FIG. 9 is the sectional view taken along a broken line G-G in the semiconductor device 100 or the semiconductor device 101 in FIG. 1.

As illustrated in FIG. 9, the p-type collector layer 16 provided on the second main surface side of the IGBT region 10 is provided so as to protrude toward the side of the diode region 20 from the boundary between the IGBT region 10 and the diode region 20 by the distance U1. As described above, when the p-type collector layer 16 is provided so as to protrude from the diode region 20, a distance between the n⁺-type cathode layer 26 of the diode region 20 and the active trench gate 11 can be increased, and even when the gate drive voltage is applied to the gate trench electrode 11a during freewheeling diode operation, the current can be prevented from flowing from a channel formed adjacent to the active trench gate 11 of the IGBT region 10 to the n⁺-type cathode layer 26. For example, the distance U1 may be 100 μm. The distance U1 may be zero or a distance smaller than 100 μm depending on the application of the semiconductor device 100 or the semiconductor device 101 that is the RC-IGBT.

### (6) Example of Structure of Termination Region 30

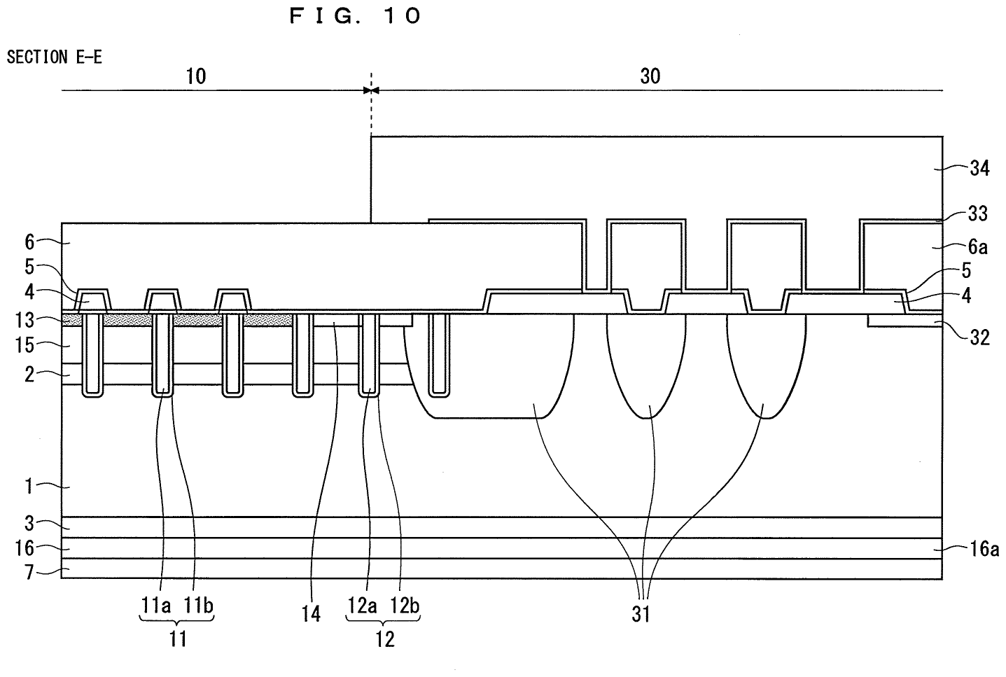

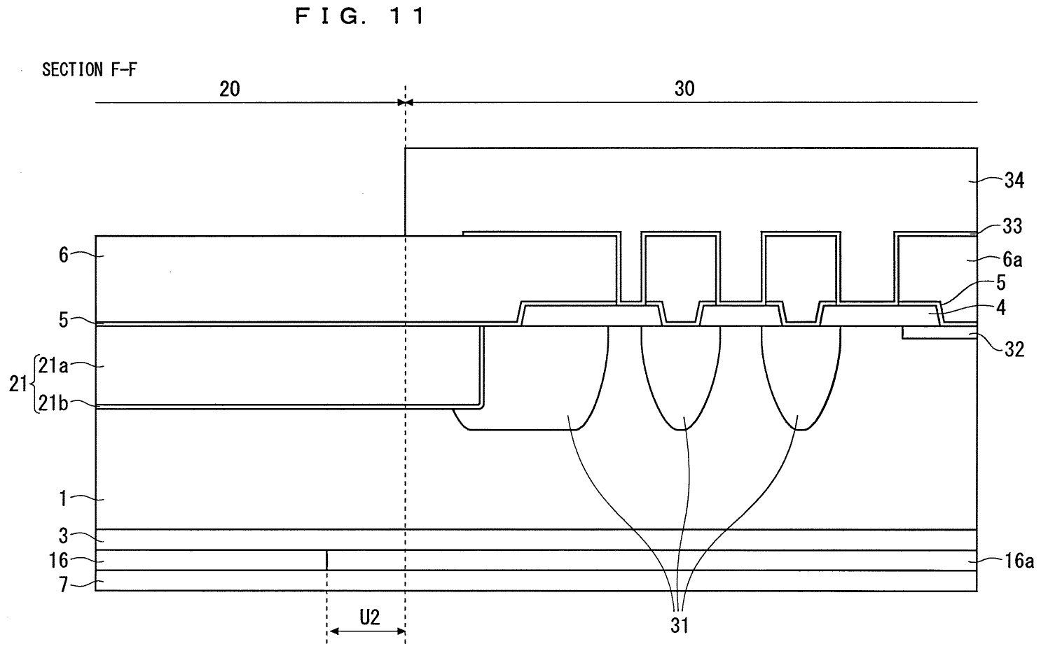

FIGS. 10 and 11 are sectional views illustrating a configuration of the termination region of the semiconductor device that is the RC-IGBT. FIG. 10 is a sectional view taken along a broken line E-E in FIG. 1 or 2, and is a sectional view from the IGBT region 10 to the termination region 30. FIG. 11 is a sectional view taken along a broken line F-F in FIG. 1, and is a sectional view from the diode region 20 to the termination region 30.

As illustrated in FIGS. 10 and 11, the termination region 30 of the semiconductor device 100 includes the n⁻-type drift layer 1 between the first main surface and the second main surface of the semiconductor substrate. The first main surface and the second main surface of the termination region 30 are flush with the first main surfaces and the second main surfaces of the IGBT region 10 and the diode region 20, respectively. The n⁻-type drift layer 1 of the termination region 30 has the same configuration as the n⁻-type drift layer 1 of the IGBT region 10 and the diode region 20, and is continuously and integrally formed.

A p-type termination well layer 31 is provided on the first main surface side of the n⁻-type drift layer 1, namely, between the first main surface of the semiconductor substrate and the n⁻-type drift layer 1. The p-type termination well layer 31 is a semiconductor layer containing, for example, boron or aluminum as the p-type impurity, and the concentration of the p-type impurity is 1.0E+14/cm³ to 1.0E+19/cm³. The p-type termination well layer 31 is provided so as to surround the cell region including the IGBT region 10 and the diode region 20. The p-type termination well layers 31 are provided in a plurality of ring shapes, and the number of the p-type termination well layers 31 to be provided is appropriately selected according to the withstand voltage design of the semiconductor device 100 or the semiconductor device 101. Furthermore, an n⁺-type channel stopper layer 32 is provided on a further outer edge side of the p-type termination well layer 31, and the n⁺-type channel stopper layer 32 surrounds the p-type termination well layer 31.

The p-type termination collector layer 16a is provided between the n⁻-type drift layer 1 and the second main surface of the semiconductor substrate. The p-type termination collector layer 16a is formed integrally and continuously with the p-type collector layer 16 provided in the cell region. Accordingly, the p-type termination collector layer 16a may be referred to as the p-type collector layer 16. Furthermore, in the configuration in which the diode region 20 is provided adjacent to the termination region 30 like the semiconductor device 100 in FIG. 1, as illustrated in FIG. 11, the p-type termination collector layer 16a is provided such that an end on the side of the diode region 20 protrudes to the diode region 20 by a distance U2. As described above, when the p-type termination collector layer 16a is provided so as to protrude to the diode region 20, the distance between the n⁺-type cathode layer 26 of the diode region 20 and the p-type termination well layer 31 can be increased, and the p-type termination well layer 31 can be prevented from operating as an anode of the diode. For example, the distance U2 may be 100 μm.

The collector electrode 7 is provided on the second main surface of the semiconductor substrate. The collector electrode 7 is integrally formed continuously from the cell region including the IGBT region 10 and the diode region 20 to the termination region 30. On the other hand, the emitter electrode 6 continuous from the cell region and a termination electrode 6a separated from the emitter electrode 6 are provided on the first main surface of the semiconductor substrate in the termination region 30.

The emitter electrode 6 and the termination electrode 6a are electrically connected through a semi-insulating film 33. For example, the semi-insulating film 33 may be a semi-insulating silicon nitride (sinSiN) film. The termination electrode 6a, the p-type termination well layer 31, and the n⁺-type channel stopper layer 32 are electrically connected through the contact hole made in the interlayer insulating film 4 provided on the first main surface of the termination region 30. In addition, in the termination region 30, a termination protection film 34 is provided so as to cover the emitter electrode 6, the termination electrode 6a, and the semi-insulating film 33. For example, the termination protection film 34 may be formed of polyimide.

### (7) Example of Method for Manufacturing RC-IGBT

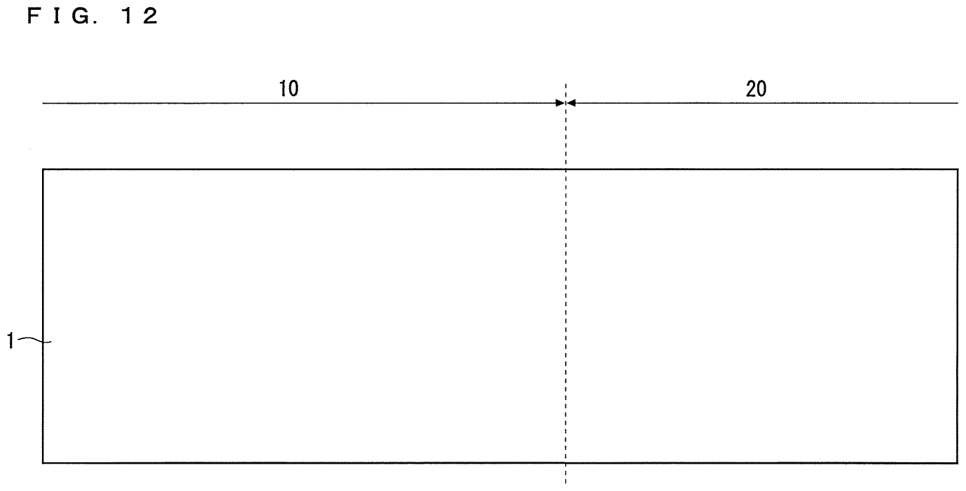

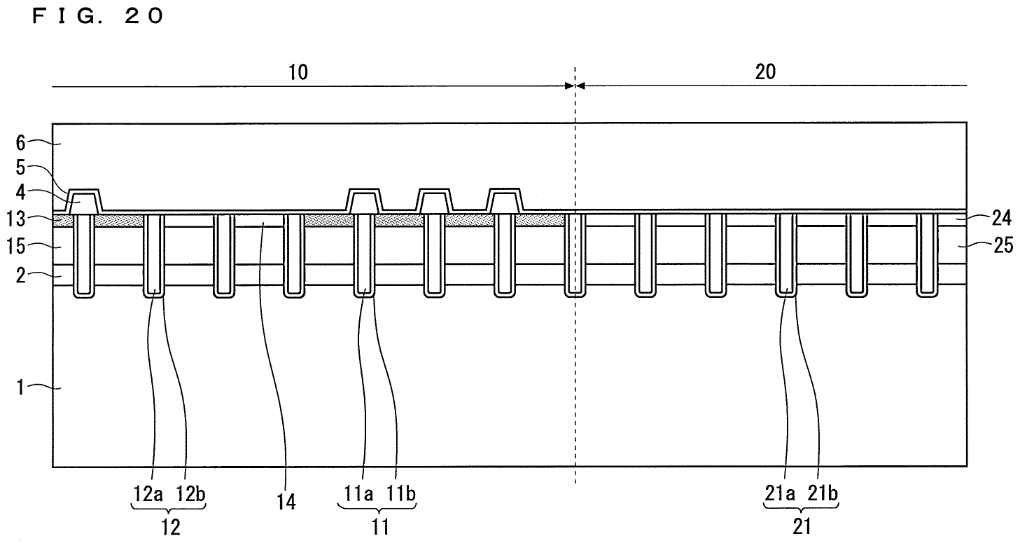

FIGS. 12 to 23 are views illustrating a method for manufacturing the semiconductor device that is the RC-IGBT. FIGS. 12 to 19 are views illustrating a process of forming the front surface side of the semiconductor device 100 or the semiconductor device 101, and FIGS. 20 to 23 are views illustrating a process of forming the back surface side of the semiconductor device 100 or the semiconductor device 101.

First, as illustrated in FIG. 12, the semiconductor substrate configuring the n⁻-type drift layer 1 is prepared. For example, what is called a floating zone (FZ) wafer manufactured by an FZ method or what is called a magnetic field applied Czochralski (MCZ) wafer manufactured by an MCZ method may be used as the semiconductor substrate, and the n-type wafer containing the n-type impurity may be used as the semiconductor substrate. The concentration of the n-type impurity contained in the semiconductor substrate is appropriately selected depending on the withstand voltage of the semiconductor device to be manufactured. For example, in the semiconductor device having the withstand voltage of 1200 V, the concentration of the n-type impurity is adjusted such that specific resistance of the n⁻-type drift layer 1 configuring the semiconductor substrate is about 40 Ω·cm to about 120 Ω·cm. As illustrated in FIG. 12, in the process of preparing the semiconductor substrate, the entire semiconductor substrate is the n⁻-type drift layer 1. the p-type or n-type impurity ion is implanted from the first main surface side or the second main surface side of the semiconductor substrate, and then diffused into the semiconductor substrate by heat treatment or the like, thereby forming the p-type or n-type semiconductor layer to manufacture the semiconductor device 100 or the semiconductor device 101.

As illustrated in FIG. 12, the semiconductor substrate configuring the n⁻-type drift layer 1 includes a region that becomes the IGBT region 10 and the diode region 20. Although not illustrated, a region that becomes the termination region 30 is provided around the region that becomes the IGBT region 10 and the diode region 20. Hereinafter, a method for manufacturing the configurations of the IGBT region 10 and the diode region 20 of the semiconductor device 100 or the semiconductor device 101 will be mainly described, and the termination region 30 of the semiconductor device 100 or the semiconductor device 101 may be manufactured by a known manufacturing method. For example, when the FLR including the p-type termination well layer 31 as the withstand voltage holding structure is formed in the termination region 30, the FLR may be formed by implanting the p-type impurity ion before the IGBT region 10 and the diode region 20 of the semiconductor device 100 or the semiconductor device 101 are processed, or the FLR may be formed by simultaneously implanting the p-type impurity ion during the implantation of the p-type impurity into the IGBT region 10 or the diode region 20 of the semiconductor device 100.

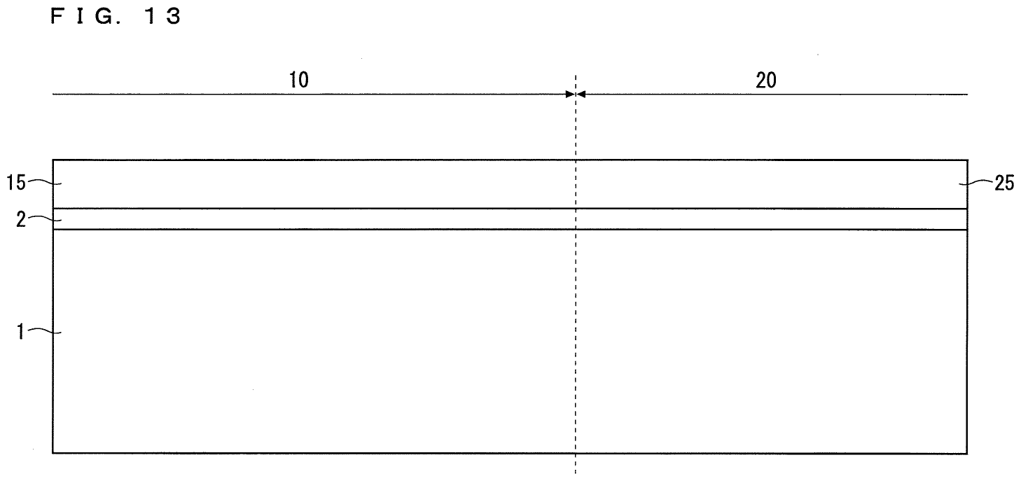

Subsequently, as illustrated in FIG. 13, the n-type impurity such as phosphorus (P) is implanted from the first main surface side of the semiconductor substrate to form the n-type carrier accumulation layer 2. In addition, the p-type impurity such as boron (B) is implanted from the first main surface side of the semiconductor substrate to form the p-type base layer 15 and the p-type anode layer 25. The n-type carrier accumulation layer 2, the p-type base layer 15 and the p-type anode layer 25 are formed by implanting the impurity ions into the semiconductor substrate and then diffusing the impurity ions by heat treatment. The n-type impurity and the p-type impurity are ion-implanted after mask processing is performed on the first main surface of the semiconductor substrate, so that the n-type impurity and the p-type impurity are selectively formed on the first main surface side of the semiconductor substrate. The n-type carrier accumulation layer 2, the p-type base layer 15, and the p-type anode layer 25 are formed in the IGBT region 10 and the diode region 20, and are connected to the p-type termination well layer 31 at the termination region 30. The mask processing refers to processing for applying a resist on the semiconductor substrate, forming an opening in a predetermined region of the resist using a photolithography technique, and forming a mask on the semiconductor substrate in order to perform the ion implantation or etching on the predetermined region of the semiconductor substrate through the opening.

The p-type base layer 15 and the p-type anode layer 25 may be formed by simultaneous ion implantation of the p-type impurity. In this case, depths or p-type impurity concentrations of the p-type base layer 15 and the p-type anode layer 25 are the same and have the same configuration. In addition, the depths or the p-type impurity concentrations of the p-type base layer 15 and the p-type anode layer 25 may be made different by separately ion-implanting the p-type impurity into the p-type base layer 15 and the p-type anode layer 25 by the mask processing.

The p-type termination well layer 31 formed in another section may be formed by ion-implanting the p-type impurity simultaneously with the p-type anode layer 25. In this case, the depths or the p-type impurity concentrations of the p-type termination well layer 31 and the p-type anode layer 25 are the same, and can have the same configuration. In addition, the p-type termination well layer 31 and the p-type anode layer 25 can be formed by the simultaneous ion implantation of the p-type impurity, and the p-type impurity of the p-type termination well layer 31 and the p-type anode layer 25 can be set to different concentrations. In this case, one or both of the masks may be used as a mesh-like mask to change an aperture ratio.

In addition, the depths or the p-type impurity concentrations of the p-type termination well layer 31 and the p-type anode layer 25 may be made different by separately ion-implanting the p-type impurity into the p-type termination well layer 31 and the p-type anode layer 25 by the mask processing. The p-type termination well layer 31, the p-type base layer 15, and the p-type anode layer 25 may be formed by the simultaneous ion implantation of the p-type impurity.

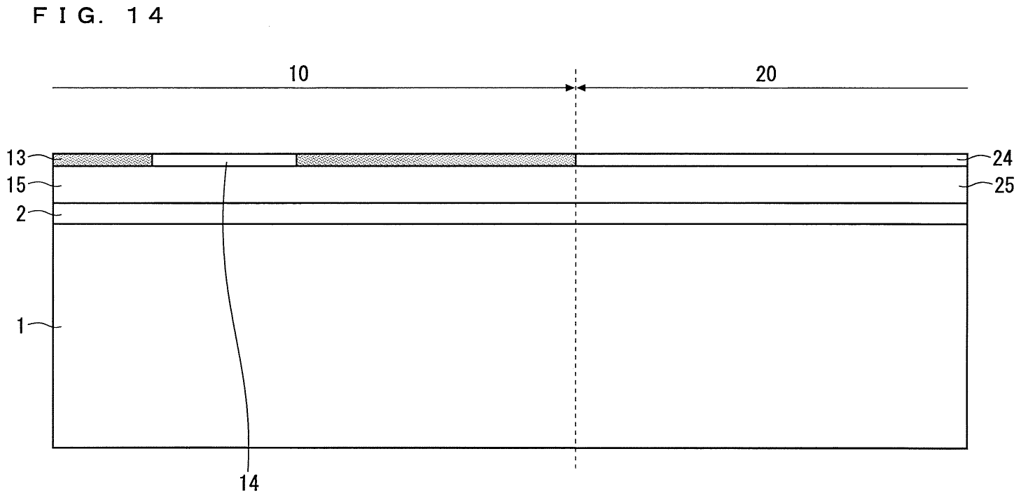

Subsequently, as illustrated in FIG. 14, the n-type impurity is selectively implanted into the first main surface side of the p-type base layer 15 of the IGBT region 10 by the mask processing to form the n⁺-type emitter layer 13. For example, the implanted n-type impurity is arsenic (As) or phosphorus (P). In addition, by the mask processing, the p-type impurity is selectively implanted into the first main surface side of the p-type base layer 15 of the IGBT region 10 to form the p⁺-type contact layer 14, and the p-type impurity is selectively implanted into the first main surface side of the p-type anode layer 25 of the diode region 20 to form the p⁺-type contact layer 24. For example, the implanted p-type impurity is boron (B) or aluminum (Al).

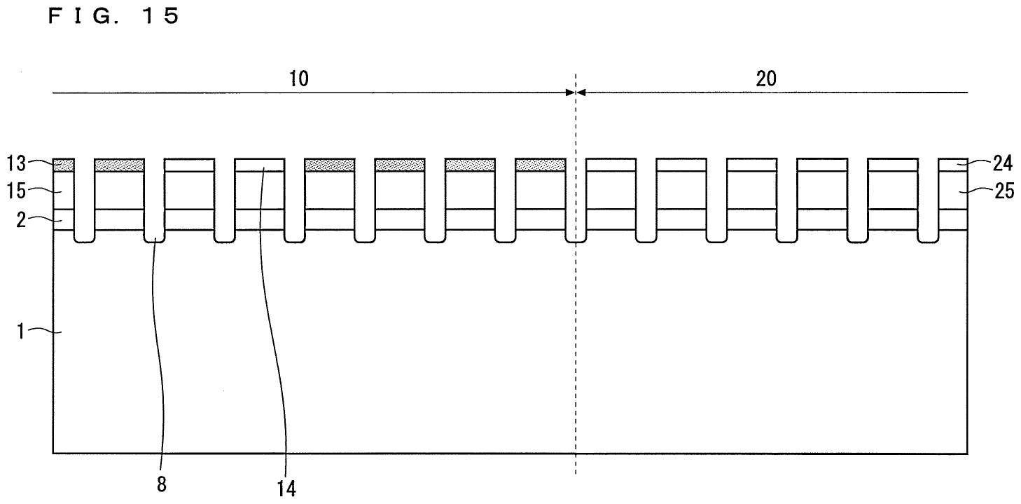

Subsequently, as illustrated in FIG. 15, a trench 8 that penetrates the p-type base layer 15 and the p-type anode layer 25 from the first main surface side of the semiconductor substrate and reaches the n⁻-type drift layer 1 is formed. In the IGBT region 10, a side wall of the trench 8 penetrating the n⁺-type emitter layer 13 configures a part of the n⁺-type emitter layer 13. After an oxide film such as SiO₂ is deposited on the semiconductor substrate, the opening is formed in the oxide film at a portion where the trench 8 is formed by the mask processing, and the semiconductor substrate is formed using the oxide film having the opening as a mask, whereby the trench 8 may be formed. In FIG. 15, the IGBT region 10 and the diode region 20 are formed with the same pitch of the trenches 8. However, the IGBT region 10 and the diode region 20 may have different pitches of the trenches 8. The pitch of the trenches 8 can be appropriately changed depending on the mask pattern of the mask processing in planar view.

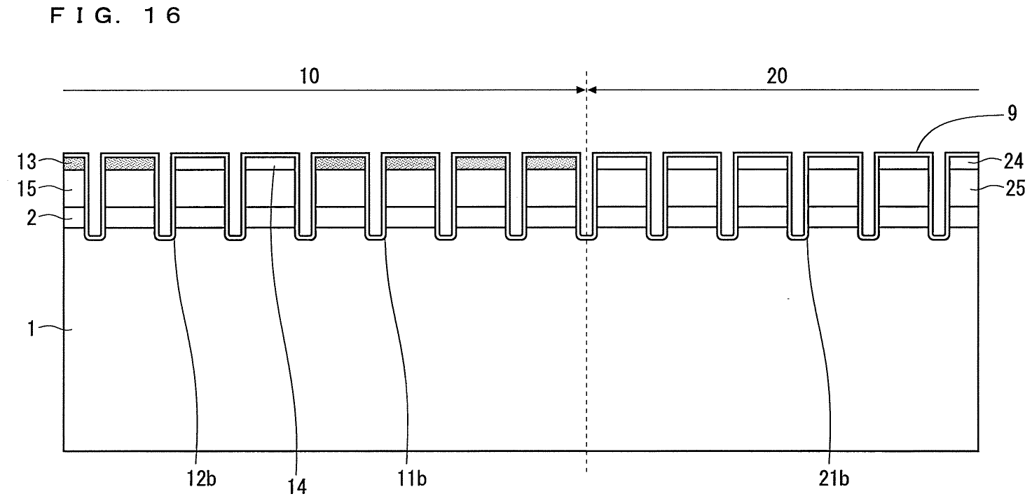

Subsequently, as illustrated in FIG. 16, the semiconductor substrate is heated in an atmosphere containing oxygen to form an oxide film 9 on the inner wall of the trench 8 and the first main surface of the semiconductor substrate. In the oxide film 9 formed on the inner wall of the trench 8, the oxide film 9 formed on the trench 8 of the IGBT region 10 is the gate trench insulating film 11b of the active trench gate 11 and the dummy trench insulating film 12b of the dummy trench gate 12. The oxide film 9 formed in the trench 8 of the diode region 20 is the diode trench insulating film 21b. The oxide film 9 formed on the first main surface of the semiconductor substrate is removed in a later process.

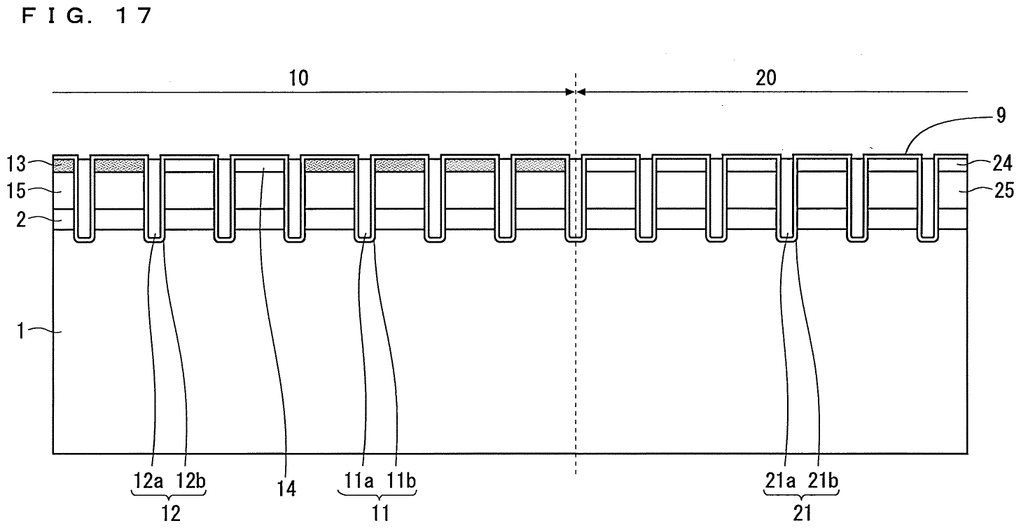

Subsequently, as illustrated in FIG. 17, polysilicon doped with the n-type or p-type impurity by chemical vapor deposition (CVD) or the like is deposited in the trench 8 in which the oxide film 9 is formed on the inner wall, and the gate trench electrode 11a, the dummy trench electrode 12a, and the diode trench electrode 21a are formed.

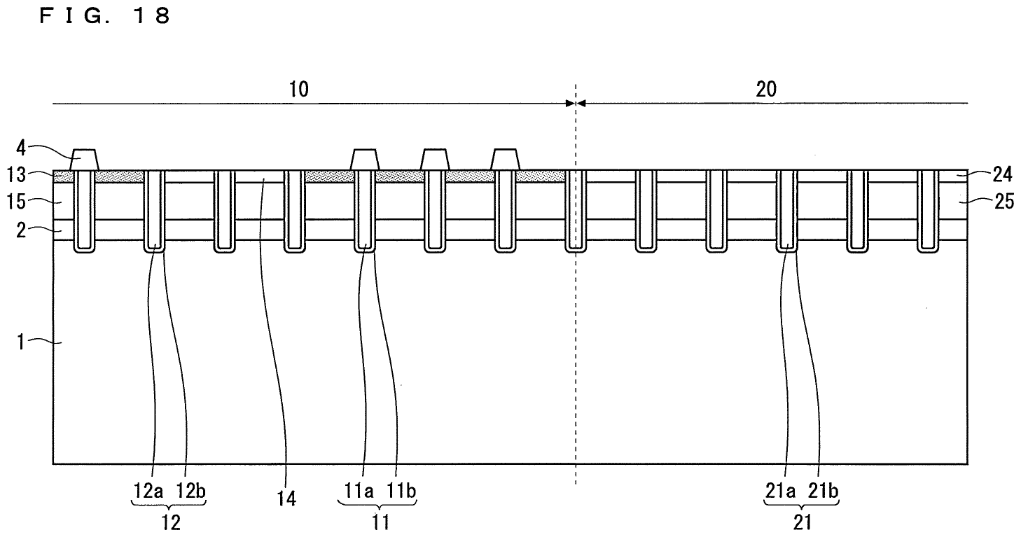

Subsequently, as illustrated in FIG. 18, after the interlayer insulating film 4 is formed on the gate trench electrode 11a of the active trench gate 11 of the IGBT region 10, the oxide film 9 formed on the first main surface of the semiconductor substrate is removed. For example, the interlayer insulating film 4 may be SiO₂. Then, the contact hole is made in the interlayer insulating film 4 deposited by the mask processing. The contact holes are made on the n⁺-type emitter layer 13, the p⁺-type contact layer 14, the p⁺-type contact layer 24, the dummy trench electrode 12a, and the diode trench electrode 21a.

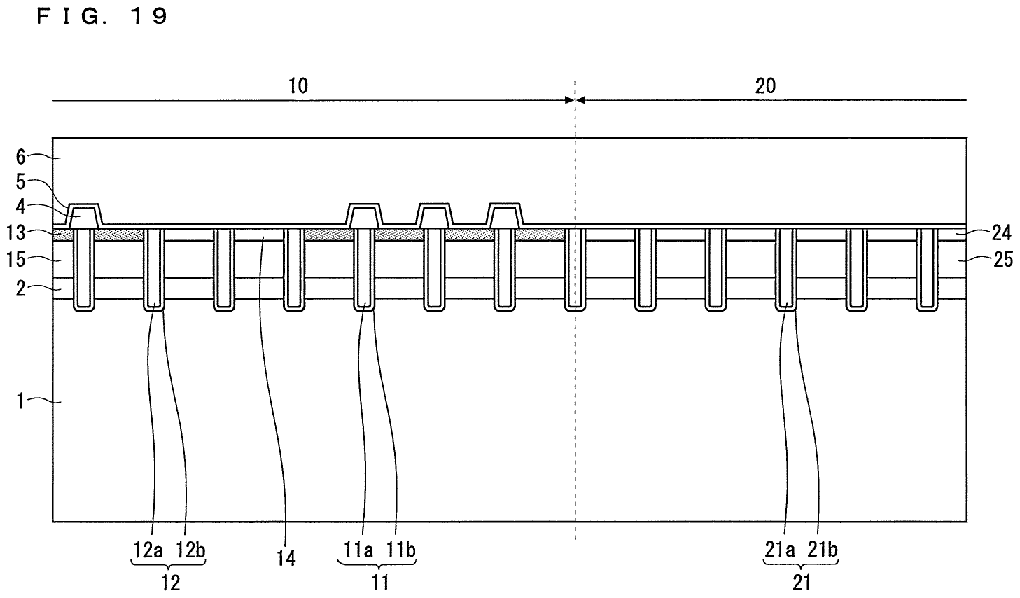

Subsequently, as illustrated in FIG. 19, the barrier metal 5 is formed on the first main surface of the semiconductor substrate and one-interlayer insulating film or the interlayer insulating film 4 having a multilayer structure including an insulating film, and the emitter electrode 6 is further formed on the barrier metal 5. The barrier metal 5 can be omitted, and is formed by depositing titanium nitride by physical vapor deposition (PVD) or CVD.

For example, the emitter electrode 6 may be formed by depositing an aluminum silicon alloy (Al—Si-based alloy) on the barrier metal 5 by PVD such as sputtering or vapor deposition. A nickel alloy (Ni alloy) may be further formed on the formed aluminum silicon alloy by electroless plating or electrolytic plating to form the emitter electrode 6. When the emitter electrode 6 is formed by plating, a thick metal film can be easily formed as the emitter electrode 6, so that a heat capacity of the emitter electrode 6 can be increased to improve heat resistance. When the nickel alloy is further formed by plating after the emitter electrode 6 made of the aluminum silicon alloy is formed by PVD, the plating treatment may be performed in order to form the nickel alloy after the second main surface side of the semiconductor substrate is processed.

Subsequently, as illustrated in FIG. 20, the second main surface side of the

semiconductor substrate is ground to thin the semiconductor substrate to a designed predetermined thickness. For example, the thickness of the ground semiconductor substrate may be 80 μm to 200 μm.

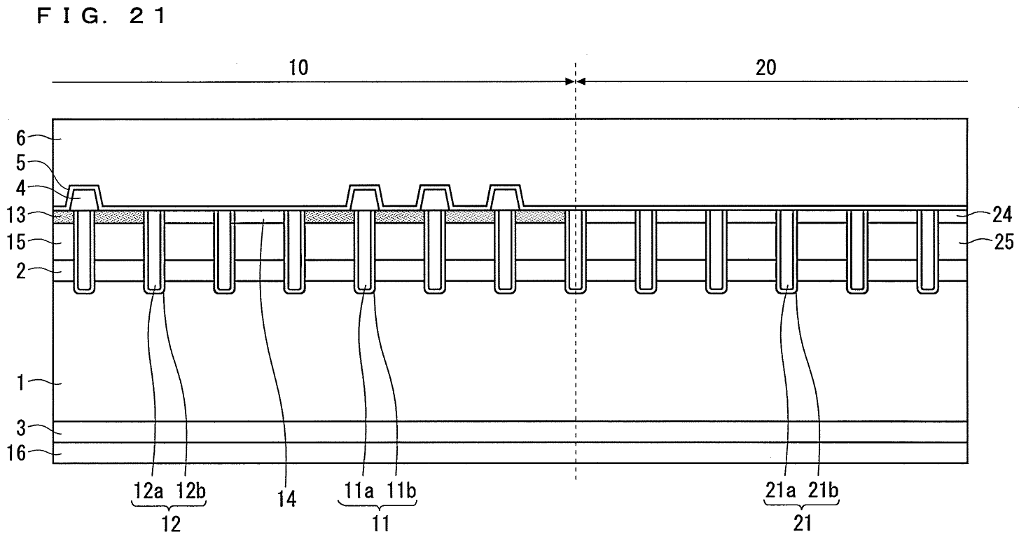

Subsequently, as illustrated in FIG. 21, the n-type impurity is implanted from the second main surface side of the semiconductor substrate to form the n-type buffer layer 3. Furthermore, the p-type impurity is implanted from the second main surface side of the semiconductor substrate to form the p-type collector layer 16. The n-type buffer layer 3 may be formed in the IGBT region 10, the diode region 20, and the termination region 30, or formed only in the IGBT region 10 or the diode region 20.

For example the n-type buffer layer 3 may be formed by implanting a phosphorus (P) ion. In addition, the n-type buffer layer 3 may be formed by implanting a proton (H⁺). Furthermore, both the proton and the phosphorus may be implanted. The proton can be injected from the second main surface of the semiconductor substrate to a deep position with relatively low acceleration energy. In addition, the depth at which the proton is injected can be relatively easily changed by changing the acceleration energy. For this reason, in forming the n-type buffer layer 3 by the proton, when the implantation is performed a plurality of times while the acceleration energy is changed, the n-type buffer layer 3 wider in the thickness direction of the semiconductor substrate than that formed of the phosphorus can be formed.

In addition, the phosphorus can increase an activation rate as the n-type impurity as compared with the proton, so that the punch-through of the depletion layer can be more reliably prevented even in the semiconductor substrate thinned by forming the n-type buffer layer 3 with the phosphorus. In order to further thin the semiconductor substrate, preferably the n-type buffer layer 3 is formed by injecting both the proton and the phosphorus, and in this case, the proton is injected at a position deeper from the second main surface than the phosphorus.

For example, the p-type collector layer 16 is formed by implanting boron (B). The p-type collector layer 16 is also formed in the termination region 30, and the p-type collector layer 16 of the termination region 30 becomes the p-type termination collector layer 16a. After the ion implantation from the second main surface side of the semiconductor substrate, the second main surface is irradiated with laser to perform laser annealing, so that implanted boron is activated to form the p-type collector layer 16. At this time, the phosphorus for the n-type buffer layer 3 injected at a relatively shallow position from the second main surface of the semiconductor substrate is also activated at the same time. On the other hand, the proton is activated at a relatively low annealing temperature such as 350° C. to 500° C., so that attention is required to be paid such that the temperature of the entire semiconductor substrate does not become higher than 350° C. to 500° C. except for the process of activating the proton after injecting the proton. The laser annealing can raise the temperature only in the vicinity of the second main surface of the semiconductor substrate, so that the laser annealing can be used for activating the n-type impurity or the p-type impurity even after the proton is implanted.

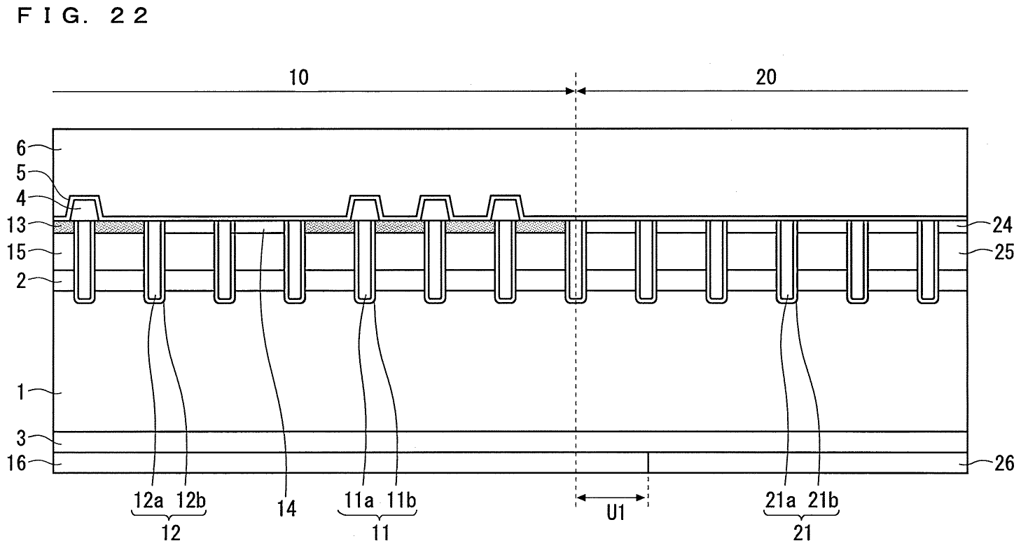

Subsequently, as illustrated in FIG. 22, the n⁺-type cathode layer 26 is formed in the diode region 20. For example, the n⁺-type cathode layer 26 may be formed by implanting the phosphorus (P). As illustrated in FIG. 22, the phosphorus is selectively implanted from the second main surface side by the mask processing such that the boundary between the p-type collector layer 16 and the n⁺-type cathode layer 26 is located at a position at the distance U1 from the boundary between the IGBT region 10 and the diode region 20 toward the side of the diode region 20. An implantation amount of the n-type impurity forming the n⁺-type cathode layer 26 is larger than the implantation amount of the p-type impurity forming the p-type collector layer 16. In FIG. 22, the depths of the p-type collector layer 16 and the n⁺-type cathode layer 26 from the second main surface are the same, but the depth of the n⁺-type cathode layer 26 is equal to or greater than the depth of the p-type collector layer 16. In the region where the n⁺-type cathode layer 26 is formed, the n-type semiconductor is required to be formed by implanting the n-type impurity into the region into which the p-type impurity is implanted, so that the concentration of the implanted p-type impurity is made higher than the concentration of the n-type impurity in the entire region where the n⁺-type cathode layer 26 is formed.

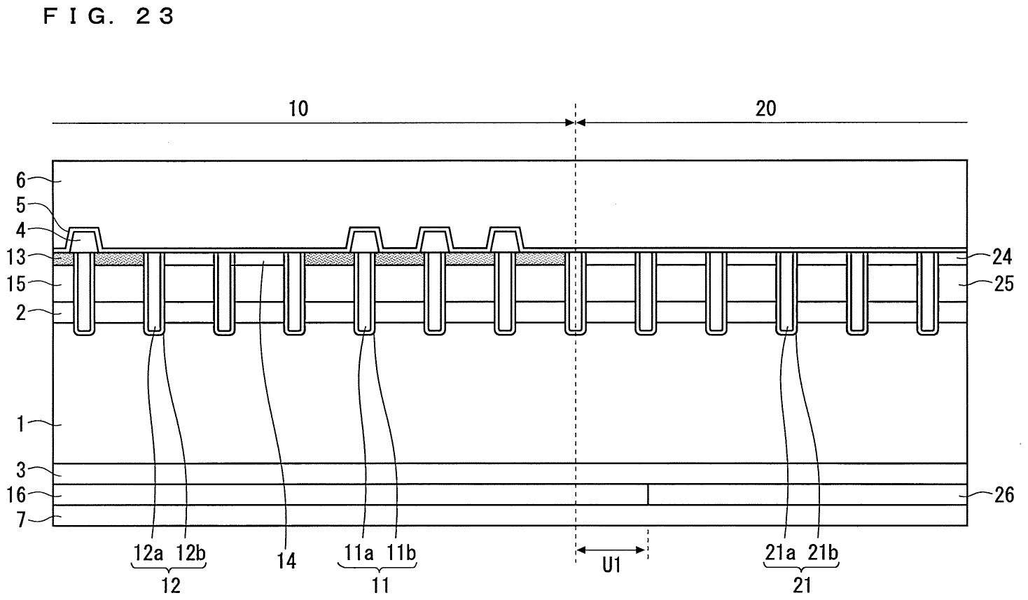

Subsequently, as illustrated in FIG. 23, the collector electrode 7 is formed on the second main surface of the semiconductor substrate. The collector electrode 7 is formed over the entire surfaces of the IGBT region 10, the diode region 20, and the termination region 30 on the second main surface. The collector electrode 7 may be formed over the entire second main surface of the n-type wafer that is the the semiconductor substrate. The collector electrode 7 may be formed by depositing an aluminum silicon alloy (Ai—Si-based alloy), titanium (Ti), or the like by PVD such as sputtering or vapor deposition, or the collector electrode 7 may be formed by laminating a plurality of metals such as an aluminum silicon alloy, titanium, nickel, or gold. Furthermore, a metal film may be further formed on the metal film formed by PVD by electroless plating or electrolytic plating to form the collector electrode 7.

The semiconductor device 100 or the semiconductor device 101 is manufactured by the above processes. A plurality of semiconductor devices 100 or semiconductor devices 101 are produced in a matrix on one n-type wafer, so that the semiconductor devices 100 or the semiconductor devices 101 are completed by being cut into individual semiconductor device 100 or semiconductor device 101 by laser dicing or blade dicing.

### (8) Structure of Contact

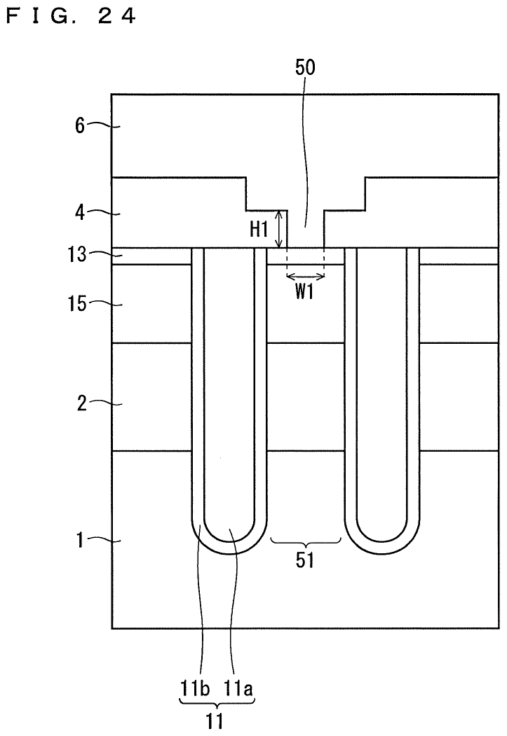

FIG. 24 is a view illustrating a configuration of a contact formed in the semiconductor device 100 or the semiconductor device 101. As an example of the contact, a contact (emitter contact) connecting the emitter electrode 6 to the n⁺-type emitter layer 13 will be described below. FIG. 24 illustrates the active trench gate 11 as the trench formed in the semiconductor substrate, but the trench may be the dummy trench gate 12 depending on the position of the contact. FIG. 24 illustrates an example in which the contact is connected to the n⁺-type emitter layer 13, but the contact may be connected to the p⁺-type contact layer 14 depending on the position of the contact.

As illustrated in FIG. 24, a contact hole 50 configuring the contact is formed in the interlayer insulating film 4 formed between the emitter electrode 6, which is a conductive film, and the semiconductor substrate. The side wall of the contact hole 50 has a stepped shape having a step. A bottom of the contact hole 50 is located on the semiconductor mesa portion 51 that is a portion between the active trench gates 11 of the semiconductor substrate, but the upper end of the contact hole 50 (the edge of the contact hole 50) is located outside the semiconductor mesa portion 51, namely, on the active trench gate 11, in planar view, the bottom of the contact hole 50 overlaps the semiconductor mesa portion 51, and the edge of the contact hole 50 overlaps the active trench gate 11.

A substantial aspect ratio of the contact hole 50 is relaxed because the side wall of the contact hole 50 has the stepped shape as described above, so that a void is prevented from being formed in the contact when the contact (the conductive film of the emitter electrode 6) is formed in the contact hole 50.

A ratio (H1/W1) of a height H1 from the bottom of the contact hole 50 to the lowest step of the side wall to a width W1 of the bottom of the contact hole 50 is equal to or less than 6, preferably equal to or less than 3, and more preferably equal to or less than 2. That is, H1 is equal to or less than six times, preferably equal to or less than three times, and more preferably equal to or less than two times W1. The lower the ratio, the better the embeddability of the conductive film in the contact hole 50.

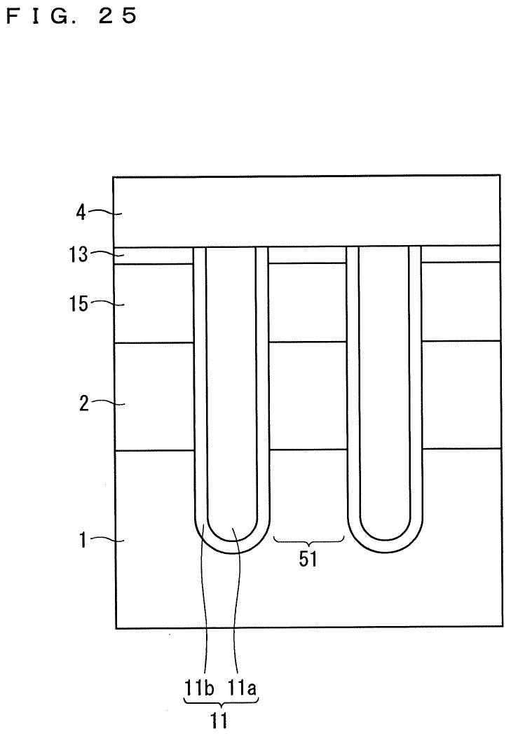

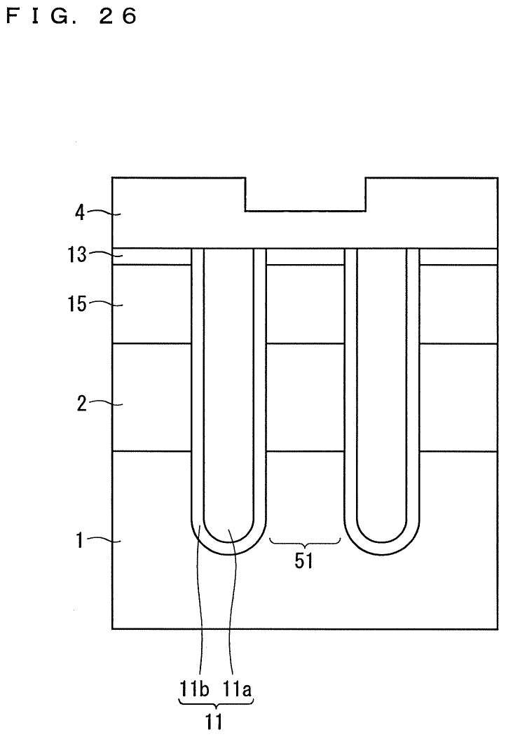

At this point, a method for forming the contact hole 50 will be described. After the interlayer insulating film 4 is formed on the semiconductor substrate as illustrated in FIG. 25, the interlayer insulating film 4 in the formation region of the contact hole 50 is selectively etched by first etching. The first etching is a half etching that removes only the upper portion of the interlayer insulating film 4. Consequently, as illustrated in FIG. 26, a recess is formed in the formation region of the contact hole 50 on the upper surface of the interlayer insulating film 4.

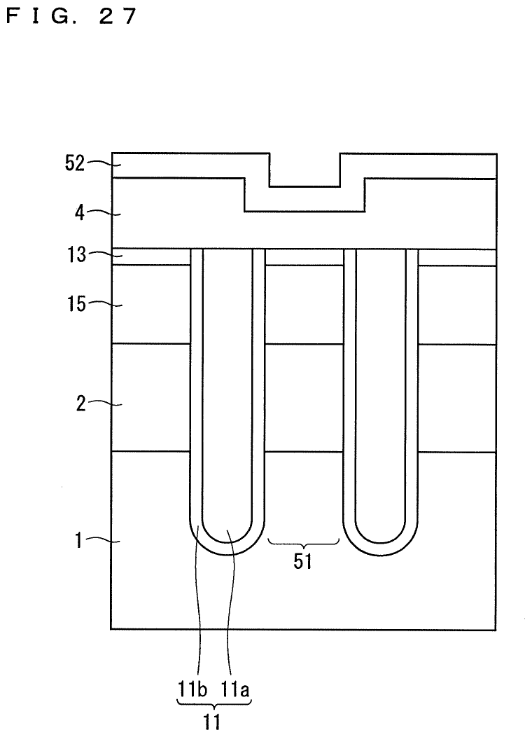

Subsequently, as illustrated in FIG. 27, an insulating film 52 such as an oxide film or a nitride film is formed on the interlayer insulating film 4. The insulating film 52 is also formed in the recess of the upper surface of the interlayer insulating film 4 formed by the first etching. A semi-insulating film or a conductive film may be used instead of the insulating film 52.

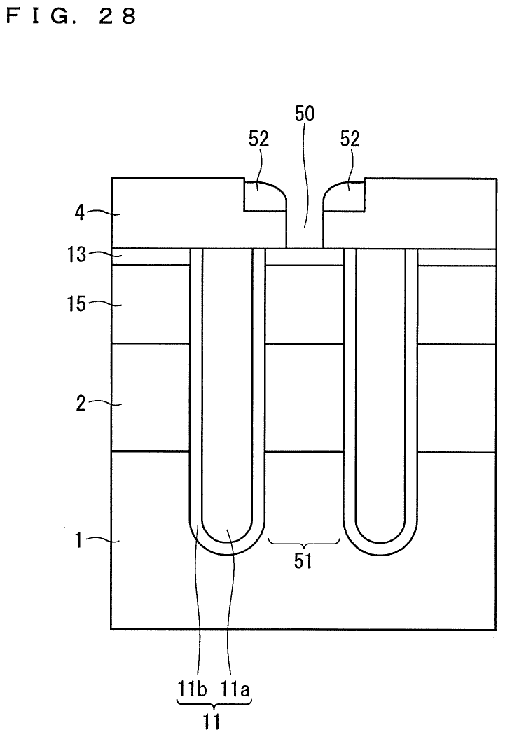

Subsequently, the insulating film 52 and the interlayer insulating film 4 in the formation region of the contact hole 50 are selectively etched by second etching. Because the insulating film 52 at a central portion of the recess of the interlayer insulating film 4 is thinner than the insulating film 52 at a peripheral portion thereof, the interlayer insulating film 4 at the central portion of the recess is etched by self-alignment in the second etching. Consequently, as illustrated in FIG. 28, the central portion of the recess of the interlayer insulating film 4 reaches the semiconductor substrate, and the contact hole 50 is made. Thereafter, the emitter electrode 6 is formed on the interlayer insulating film 4 to obtain the contact having the configuration in FIG. 24.

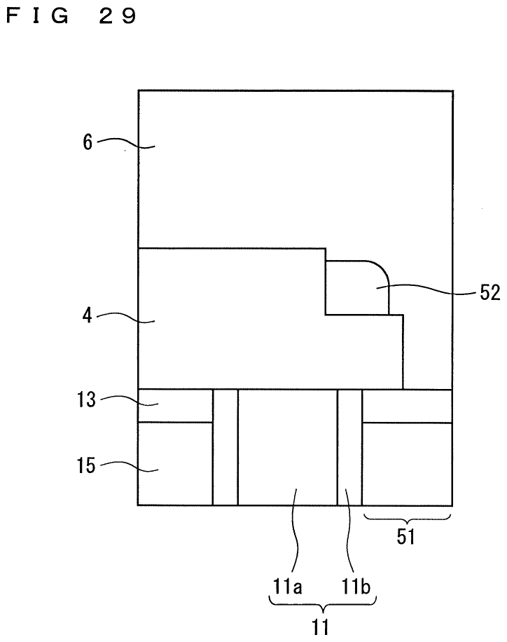

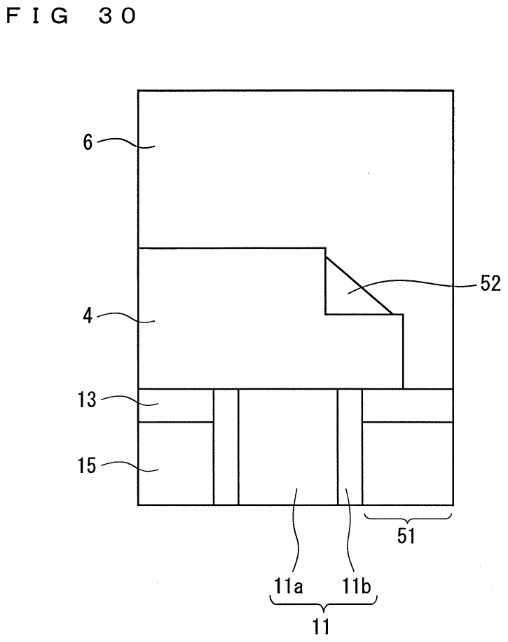

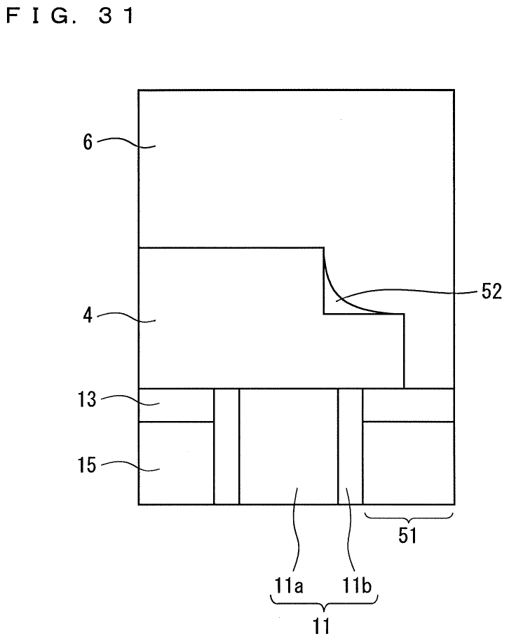

As illustrated in FIG. 28, in the process of making the contact hole 50 by the self-alignment, the insulating film 52 remains as a frame-shaped member on the outer peripheral portion of the recess of the interlayer insulating film 4, namely, on the step on the side wall of the contact hole 50. The frame-shaped insulating film 52 may be removed or left as it is. When the frame-shaped insulating film 52 is left, the upper end of the insulating film 52 is preferably lower than the upper surface of the interlayer insulating film 4, or the width of the opening of the frame-shaped insulating film 52 is preferably larger than the width (W1) of the bottom of the contact hole 50, or both of them are preferable. In addition, the sectional shape of the frame-shaped insulating film 52 may be a round shape with a bulged side surface (FIG. 29), a triangular shape with an inclined side surface (FIG. 30), or a dent shape with a recessed side surface (FIG. 31). When the frame-shaped insulating film 52 is left, the embeddability of the conductive film into the contact hole 50 is improved.

In addition, the edge of the step on the side wall of the contact hole 50 may be chamfered in the second etching or by another etching to form the edge into a round shape. The embeddability of the conductive film in the contact hole 50 is further improved.

The conductive film configuring the emitter electrode 6 is preferably Al or a metal having lower electric resistance than Al. As described above, the barrier metal 5 may be formed on the lower surface of the emitter electrode 6. For example, when Cu is used as the material of the conductive film of the emitter electrode 6, the material of the conductive film can be prevented from diffusing into the interlayer insulating film 4 or the semiconductor substrate.

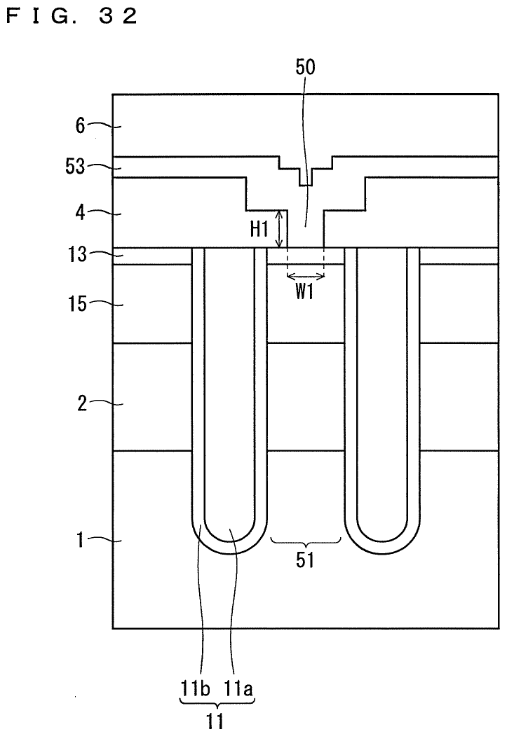

As illustrated in FIG. 32, the emitter electrode 6 may have a two-layer structure including the lower conductive film 53. The lower conductive film 53 is preferably formed of Ti, W, Mo, or the like having good embeddability. Furthermore, the lower conductive film 53 may have a plug shape embedded in the contact hole 50. Stress relaxation can be expected when the lower conductive film 53 is formed into a plug shape.

The interlayer insulating film 4 may have a multilayer structure in which at least two kinds of conductive films are laminated. For example, when a selection ratio of etching is different for each layer of the multilayer structure, the shape of the contact hole 50 can be controlled.

The side wall of the contact hole 50 may have at least two steps. When the number of steps is increased, the embeddability of the conductive film in the contact hole 50 is improved. The contact hole 50 having at least two steps can be formed by repeating the processes described with reference to FIGS. 26 to 28.

### Second Preferred Embodiment

In a second preferred embodiment, another configuration of the contact formed in the semiconductor device 100 or the semiconductor device 101 will be described.

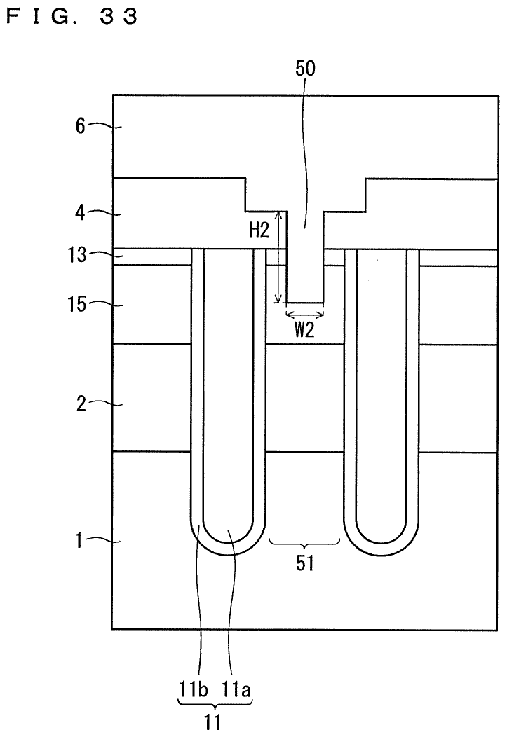

FIG. 33 is a view illustrating a configuration of the contact according to the second preferred embodiment. Similarly to the first embodiment, the contact hole 50 configuring the contact is formed in the interlayer insulating film 4 formed between the emitter electrode 6, which is the conductive film, and the semiconductor substrate. The side wall of the contact hole 50 has a stepped shape having a step.

In the second preferred embodiment, the contact hole 50 enters the inside of the semiconductor mesa portion 51 (the inside of the p-type base layer 15) that is the portion between the active trench gates 11 of the semiconductor substrate. Consequently, the position of the bottom of the contact hole 50 is lower than the upper surface (that is, the first main surface) of the semiconductor substrate. In the example of FIG. 33, the contact hole 50 penetrates the n⁺-type emitter layer 13 and reaches the p-type base layer 15 under the n⁺-type emitter layer 13. Thus, a hole extraction efficiency is improved, and a latch-up tolerance is improved.

The upper end (the edge of the opening) of the opening of the contact hole 50 is located outside the semiconductor mesa portion 51, namely, on the active trench gate 11, in planar view, the bottom of the contact hole 50 overlaps the semiconductor mesa portion 51, and the edge of the contact hole 50 overlaps the active trench gate 11.

A ratio (H2/W2) of a height H2 from the bottom of the contact hole 50 to the lowest step of the side wall to a width W2 of the bottom of the contact hole 50 is equal to or less than 6, preferably equal to or less than 3, and more preferably equal to or less than 2. That is, H2 is equal to or less than six times, preferably equal to or less than three times, and more preferably equal to or less than two times W2.

The contact hole 50 of the second exemplary embodiment can also be formed by the method described with reference to FIGS. 25 to 28. However, the second etching needs to be performed until the contact hole 50 enters the inside of the semiconductor substrate.

The frame-shaped insulating film 52 formed in the process of forming the contact hole 50 by the self-alignment may be removed or left as it is. When the frame-shaped insulating film 52 is left, the upper end of the insulating film 52 is preferably lower than the upper surface of the interlayer insulating film 4, or the width of the opening of the frame-shaped insulating film 52 is preferably larger than the width (W2) of the bottom portion of the contact hole 50, or both of them are preferable. In addition, the sectional shape of the frame-shaped insulating film 52 may be the round shape having the bulged side surface (FIG. 29), the triangular shape with an inclined side surface (FIG. 30), or the dent shape with the recessed side surface (FIG. 31).

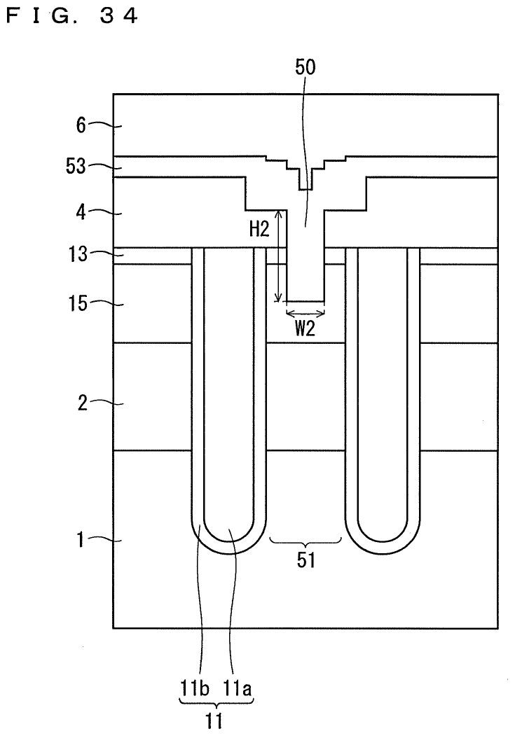

The conductive film configuring the emitter electrode 6 is preferably Al or a metal having lower electric resistance than Al. As described above, the barrier metal 5 may be formed on the lower surface of the emitter electrode 6. As illustrated in FIG. 34, the emitter electrode 6 may have the two-layer structure including the lower conductive film 53. The lower conductive film 53 is preferably formed of Ti, W, Mo, or the like. Furthermore, the lower conductive film 53 may have a plug shape embedded in the contact hole 50.

The interlayer insulating film 4 may have a multilayer structure in which at least two kinds of conductive films are laminated. The side wall of the contact hole 50 may have at least two steps. The contact hole 50 having at least two steps can be formed by repeating the processes described with reference to FIGS. 26 to 28.

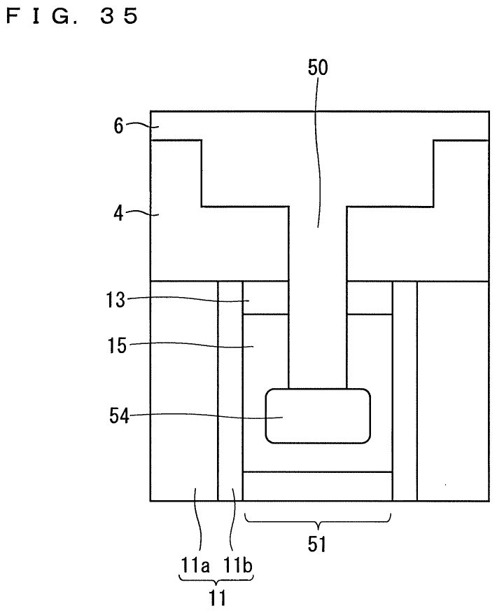

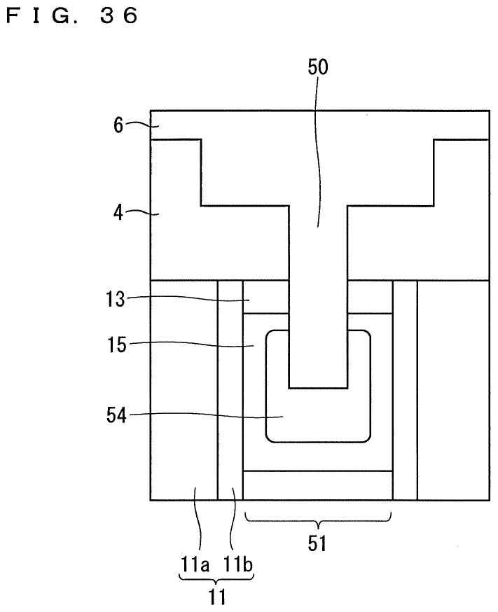

As illustrated in FIG. 35, a p-type high-concentration layer 54 that is in contact with the bottom of the contact hole 50 and locally has the high impurity concentration may be formed in the p-type base layer 15 of the semiconductor mesa portion 51. When the p-type high-concentration layer 54 is provided, the hole extraction efficiency is further improved. As illustrated in FIG. 36, the p-type high-concentration layer 54 may be formed so as to surround the contact hole 50.

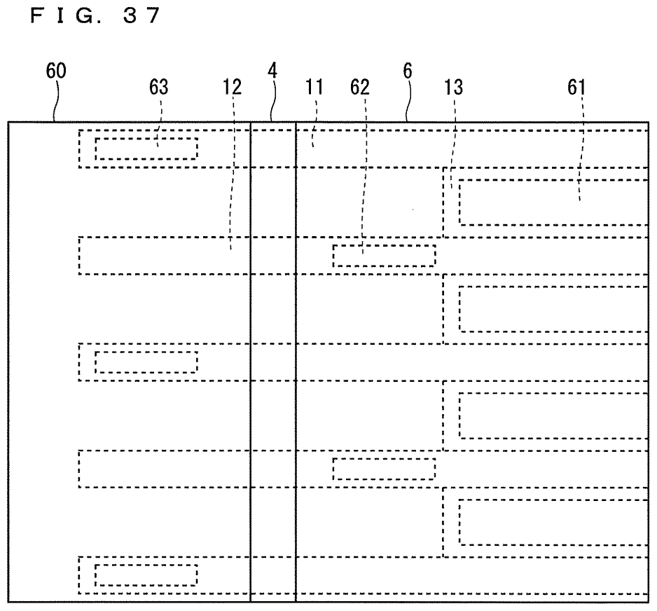

FIG. 37 is a view illustrating a disposition example of contacts in the semiconductor device 100 or the semiconductor device 101. Examples of the contact hole formed in the interlayer insulating film 4 of the semiconductor device 100 or the semiconductor device 101 include an emitter contact hole 61 that connects the emitter electrode 6 to the n⁺-type emitter layer 13 of the semiconductor mesa portion 51, a dummy trench contact hole 62 that connects the emitter electrode 6 to the dummy trench electrode 12a, and an active trench contact hole 63 that connects a gate wiring 60 to the gate trench electrode 11a of the active trench gate 11.

As illustrated in FIG. 37, the emitter contact hole 61 is formed on the n⁺-type emitter layer 13 under the emitter electrode 6, the dummy trench contact hole 62 is formed on the dummy trench gate 12 under the emitter electrode 6, and the active trench contact hole 63 is formed on the active trench gate 11 under the gate wiring 60. When the contact hole 50 of the first preferred embodiment or the second preferred embodiment is applied to the emitter contact hole 61, the upper end of the emitter contact hole 61 protrudes from the semiconductor mesa portion 51 and is located on the active trench gate 11 or the dummy trench gate 12. Consequently, in this case, as illustrated in FIG. 37, the positions of the emitter contact hole 61 and the dummy trench contact hole 62 may be disposed so as not to overlap each other in the direction orthogonal to the extending direction of the active trench gate 11.

The embodiments can be freely combined, and the embodiments can be appropriately modified or omitted.

### Appendixes

Hereinafter, various aspects of the present disclosure will be collectively described as appendixes.

### Appendix 1

A semiconductor device comprising:
a semiconductor substrate on which a plurality of trenches are formed;
an interlayer insulating film formed on the semiconductor substrate;
a contact hole made in the interlayer insulating film; and
an electrode that is formed on the interlayer insulating film and connected to a semiconductor mesa portion that is a portion between the trenches of the semiconductor substrate through the contact hole,
wherein a side wall of the contact hole has a stepped shape having at least one step, and
a bottom of the contact hole is located on the semiconductor mesa portion and an upper end of the contact hole is located outside the semiconductor mesa portion.

### Appendix 2

The semiconductor device according to Appendix 1, wherein the bottom of the contact hole enters the semiconductor mesa portion.

### Appendix 3

The semiconductor device according to Appendix 2, wherein a high-concentration layer locally having a high impurity concentration is formed in the semiconductor mesa portion so as to be in contact with the bottom of the contact hole.

### Appendix 4

The semiconductor device according to Appendix 3, wherein the high-concentration layer is formed so as to surround the contact hole.

### Appendix 5

The semiconductor device according to any one of Appendixes 1 to 4, wherein a height from the bottom of the contact hole to the step lowest in the side wall is equal to or less than six times a width of the bottom of the contact hole.

### Appendix 6

The semiconductor device according to any one of Appendixes 1 to 5, wherein the electrode includes Al or a metal having electric resistance lower than that of Al.

### Appendix 7

The semiconductor device according to any one of Appendixes 1 to 6, wherein the electrode includes a barrier metal on a lower surface.

### Appendix 8

The semiconductor device according to any one of Appendixes 1 to 7, wherein the electrode has a multilayer structure having a lower conductive film containing any of Ti, W, and Mo.

### Appendix 9

The semiconductor device according to Appendix 8, wherein the lower conductive film has a plug shape embedded in the contact hole.

### Appendix 10

The semiconductor device according to any one of Appendixes 1 to 9, wherein the interlayer insulating film has a multilayer structure in which at least two kinds of conductive films are laminated.

### Appendix 11

The semiconductor device according to any one of Appendixes 1 to 10, wherein the side wall of the contact hole has a stepped shape having at least two steps.

### Appendix 12

The semiconductor device according to any one of Appendixes 1 to 11, wherein a frame-shaped member is formed on the step on the side wall of the contact hole, and an upper end of the frame-shaped member is lower than an upper surface of the interlayer insulating film.

### Appendix 13

The semiconductor device according to any one of Appendixes 1 to 12, wherein the frame-shaped member is formed on the step on the side wall of the contact hole, and a width of an opening of the frame-shaped member is wider than a width of the bottom of the contact hole.

### Appendix 14

The semiconductor device according to Appendixes 12 or 13, wherein the frame-shaped member is an oxide film, a nitride film, a semi-insulating film, or a conductive film.

### Appendix 15

The semiconductor device according to any one of Appendixes 12 to 14, wherein a sectional shape of the frame-shaped member is a round shape having a bulged side surface, a triangular shape having an inclined flat side surface, or a dent shape having a recessed side surface.

### Appendix 16

The semiconductor device according to any one of Appendixes 1 to 15, wherein an edge of the step on the side wall of the contact hole is chamfered.

### Appendix 17

The semiconductor device according to any one of Appendixes 1 to 16, further comprising a trench contact hole that is made in the interlayer insulating film and connected to a trench electrode in the trench, wherein a position of the contact hole and a position of the trench contact hole do not overlap each other in a direction orthogonal to an extending direction of the trench.

### Appendix 18

The semiconductor device described in any one of Appendixes 1 to 17, wherein the semiconductor substrate is made of a wide band gap semiconductor.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor substrate on which a plurality of trenches are formed;
an interlayer insulating film formed on the semiconductor substrate;
a contact hole made in the interlayer insulating film; and
an electrode that is formed on the interlayer insulating film and connected to a semiconductor mesa portion that is a portion between the trenches of the semiconductor substrate through the contact hole,
wherein a side wall of the contact hole has a stepped shape having at least one step, and
a bottom of the contact hole is located on the semiconductor mesa portion and an upper end of the contact hole is located outside the semiconductor mesa portion.

2. The semiconductor device according to claim 1, wherein the bottom of the contact hole enters the semiconductor mesa portion.

3. The semiconductor device according to claim 2, wherein a high-concentration layer locally having a high impurity concentration is formed in the semiconductor mesa portion so as to be in contact with the bottom of the contact hole.

4. The semiconductor device according to claim 3, wherein the high-concentration layer is formed so as to surround the contact hole.

5. The semiconductor device according to claim 1, wherein a height from the bottom of the contact hole to the step lowest in the side wall is equal to or less than six times a width of the bottom of the contact hole.

6. The semiconductor device according to claim 1, wherein the electrode includes Al or a metal having electric resistance lower than that of Al.

7. The semiconductor device according to claim 1, wherein the electrode includes a barrier metal on a lower surface.

8. The semiconductor device according to claim 1, wherein the electrode has a multilayer structure having a lower conductive film containing any of Ti, W, and Mo.

9. The semiconductor device according to claim 8, wherein the lower conductive film has a plug shape embedded in the contact hole.

10. The semiconductor device according to claim 1, wherein the interlayer insulating film has a multilayer structure in which at least two kinds of conductive films are laminated.

11. The semiconductor device according to claim 1, wherein the side wall of the contact hole has a stepped shape having at least two steps.

12. The semiconductor device according to claim 1, wherein
a frame-shaped member is formed on the step on the side wall of the contact hole, and
an upper end of the frame-shaped member is lower than an upper surface of the interlayer insulating film.

13. The semiconductor device according to claim 1, wherein
the frame-shaped member is formed on the step on the side wall of the contact hole, and
a width of an opening of the frame-shaped member is wider than a width of the bottom of the contact hole.

14. The semiconductor device according to claim 12, wherein the frame-shaped member is an oxide film, a nitride film, a semi-insulating film, or a conductive film.

15. The semiconductor device according to claim 13, wherein the frame-shaped member is an oxide film, a nitride film, a semi-insulating film, or a conductive film.

16. The semiconductor device according to claim 12, wherein a sectional shape of the frame-shaped member is a round shape having a bulged side surface, a triangular shape having an inclined flat side surface, or a dent shape having a recessed side surface.

17. The semiconductor device according to claim 13, wherein a sectional shape of the frame-shaped member is a round shape having a bulged side surface, a triangular shape having an inclined flat side surface, or a dent shape having a recessed side surface.

18. The semiconductor device according to claim 1, wherein an edge of the step on the side wall of the contact hole is chamfered.

19. The semiconductor device according to claim 1, further comprising a trench contact hole that is made in the interlayer insulating film and connected to a trench electrode in the trench,
wherein a position of the contact hole and a position of the trench contact hole do not overlap each other in a direction orthogonal to an extending direction of the trench.

20. The semiconductor device according to claim 1, wherein the semiconductor substrate is made of a wide band gap semiconductor.
